(19) United States
(12) Patent Application Publication
(10) Pub. No.: US 2025/0203941 A1
(43) Pub. Date: Jun. 19, 2025

(54) GATE STRUCTURE PROFILES IN SEMICONDUCTOR DEVICES

(71) Applicant: Taiwan Semiconductor Manufacturing Company, Ltd., Hsinchu (TW)

(72) Inventors: Kuei-Yu KAO, Hsinchu (TW); Shih-Yao LIN, New Taipei City (TW); Chih-Chung CHIU, Hsinchu (TW); Chen-Chin LIAO, Yilan (TW); Chun-Yu LIN, Yilan (TW); Yung-Chi CHANG, Hsinchu (TW); Chih-Han LIN, Hsinchu (TW); Min-Chiao LIN, Hsinchu City (TW)

(73) Assignee: Taiwan Semiconductor Manufacturing Company, Ltd., Hsinchu (TW)

(21) Appl. No.: 18/766,620

(22) Filed: Jul. 8, 2024

Related U.S. Application Data
(60) Provisional application No. 63/609,718, filed on Dec. 13, 2023.

(51) Int. Cl. H01L 29/423; H01L 21/28; H01L 29/06; H01L 29/66; H01L 29/775; H01L 29/786

(52) U.S. Cl. CPC H10D 30/6735; H01L 21/28114; H10D 30/014; H10D 30/43; H10D 30/6757; H10D 62/121; H10D 64/017

(57) ABSTRACT

A semiconductor device and a method of fabricating the semiconductor device are disclosed. The semiconductor device includes a substrate, a base structure with first and second base portions disposed on the substrate, an isolation region disposed on the substrate and adjacent to the base structure, a nanostructured channel region disposed on the first base portion, a source/drain region disposed on the second base portion, a gate structure, and a gate spacer disposed along sidewalls of the gate structure and between the gate structure and the isolation region. The gate structure includes an outer gate portion comprising a tapered cross-sectional profile and disposed on the isolation region and an inner gate portion including a non-tapered cross-sectional profile and disposed on the nanostructured channel region.

### CROSS-REFERENCE TO RELATED APPLICATIONS

This application claims the benefit of U.S. Provisional Patent Application No. 63/609,718, titled “Parasitic Capacitance Reduction for Device Boost,” filed Dec. 13, 2023, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with gate structures having tapered cross-sectional profiles, in accordance with some embodiments.

FIG. 1B illustrates a top-down view of a semiconductor device with gate structures having tapered cross-sectional profiles, in accordance with some embodiments.

FIGS. 2A-2C, 3A-3C, and 4A-4C illustrate different cross-sectional views of a semiconductor device with gate structures having tapered cross-sectional profiles, in accordance with some embodiments.

FIG. 5 is a flow diagram of a method for fabricating a semiconductor device with gate structures having tapered cross-sectional profiles, in accordance with some embodiments.

FIGS. 6, 7A-7D, 8A-8D, 9A-9D, 10A-10D, 11A-11D, 12A-12C, 13A-13C, 14A-14C, and 15A-15C illustrate isometric and cross-sectional views of a semiconductor device with gate structures having tapered cross-sectional profiles at various stages of its fabrication process, in accordance with some embodiments.

FIG. 16 is a flow diagram of a method for fabricating another semiconductor device with gate structures having tapered cross-sectional profiles, in accordance with some embodiments.

FIGS. 17A-17D, 18A-18D, 19A-19D, 20A-20D, 21A-21C, 22A-22C, 23A-23C, 24A-24C, and 25A-25C illustrate isometric and cross-sectional views of a semiconductor device with gate structures having tapered cross-sectional profiles at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

A GAA FET can include a base structure (also referred to as “a sheet base” and “a fin base”) disposed on a substrate, a shallow trench isolation (STI) region disposed adjacent to the base structure and on the substrate, source/drain (S/D) regions disposed on the substrate, nanostructured channel regions disposed on the base structure and between the S/D regions, and a gate structure (also referred to as a “GAA structure”) surrounding each of the nanostructured channel regions. The GAA structure includes an outer gate portion disposed on the STI region and an inner gate portion disposed on the nanostructured channel regions. The inner gate portion includes a top gate portion disposed on the topmost nanostructured channel region and a bottom gate portion disposed between the base structure and the bottommost nanostructured channel region.

One of the challenges of forming the GAA structure is preventing the bottom gate portion from extending into the base structure during the formation of the GAA structure, which places the bottom gate portion close to the S/D regions and increases the parasitic capacitance in the GAA FET. The bottom gate portion extends into the base structure due to a trench formed in the base structure during the formation of the GAA structure in a gate replacement process. The gate replacement process includes forming a sacrificial gate structure (also referred to as a “dummy gate structure”) with a portion on the STI region, etching the sacrificial gate structure to form a gate opening, and forming the GAA structure in the gate opening. During the etching of the sacrificial gate structure, the STI region below the sacrificial gate structure is etched, which leads to the base structure, adjacent to the STI region, being etched and the trench in the base structure being formed.

To overcome the abovementioned challenges, the present disclosure provides example structures and methods for improving the bottom surface profiles of the bottom gate portion of the GAA structure, which increases the spacing between the bottom gate portion and the S/D regions. Increasing the spacing between the bottom gate portion and the S/D regions can reduce or minimize the parasitic capacitance in the GAA FET, which can improve the reliability and performance of the GAA FET. In some embodiments, the portion of the sacrificial gate structure on the STI region can be separated by a spacer to prevent the etching of the STI region during the removal of the sacrificial gate structure. Preventing the etching of the STI region can prevent the etching of the base structure and the formation of the trench in the base structure. As a result, the bottom gate portion can be formed with a substantially planar bottom surface profile. In some embodiments, the portion of the sacrificial gate structure directly on the STI region can be formed with a tapered cross-sectional profile to prevent or minimize the etching of the STI region during the removal of the sacrificial gate structure. As a result, the formation of the trench in the base structure can be prevented or a narrow trench can be formed in the base structure. In some embodiments, the trench can be narrower than that formed with sacrificial gate structures having non-tapered (e.g., rectangular) cross-sectional profiles on the STI regions. Thus, by modifying the profiles of the sacrificial gate structure portions on the STI regions, the bottom surface profiles of the bottom gate portion can be improved to reduce or minimize the parasitic capacitance in the GAA FET.

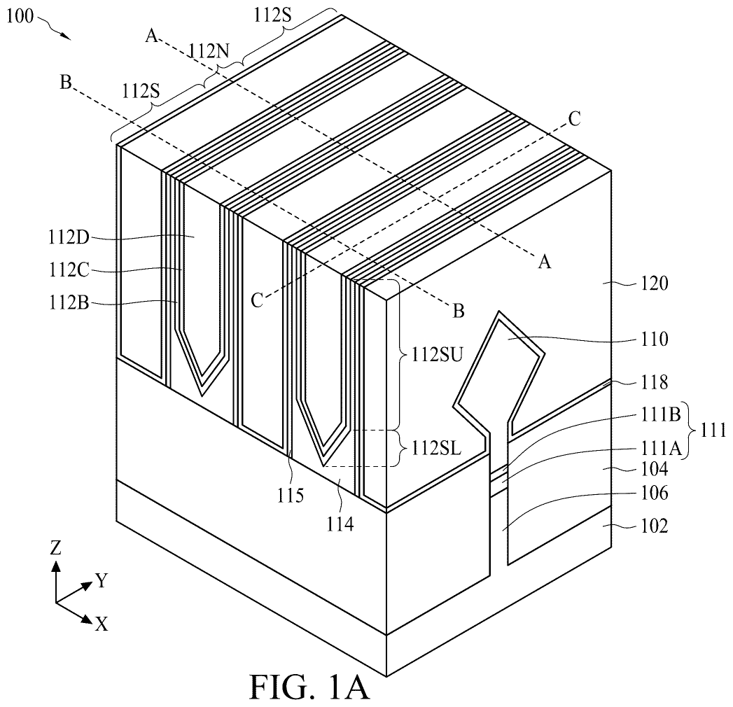

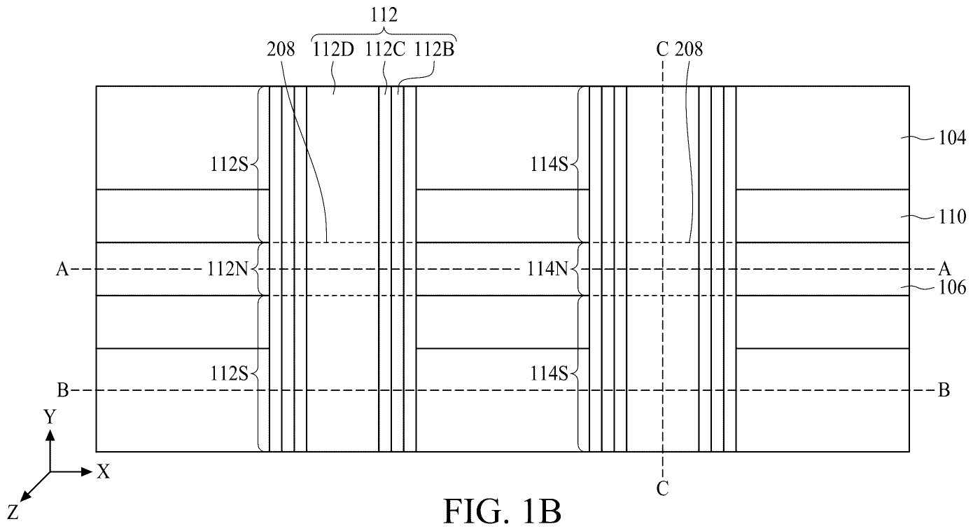

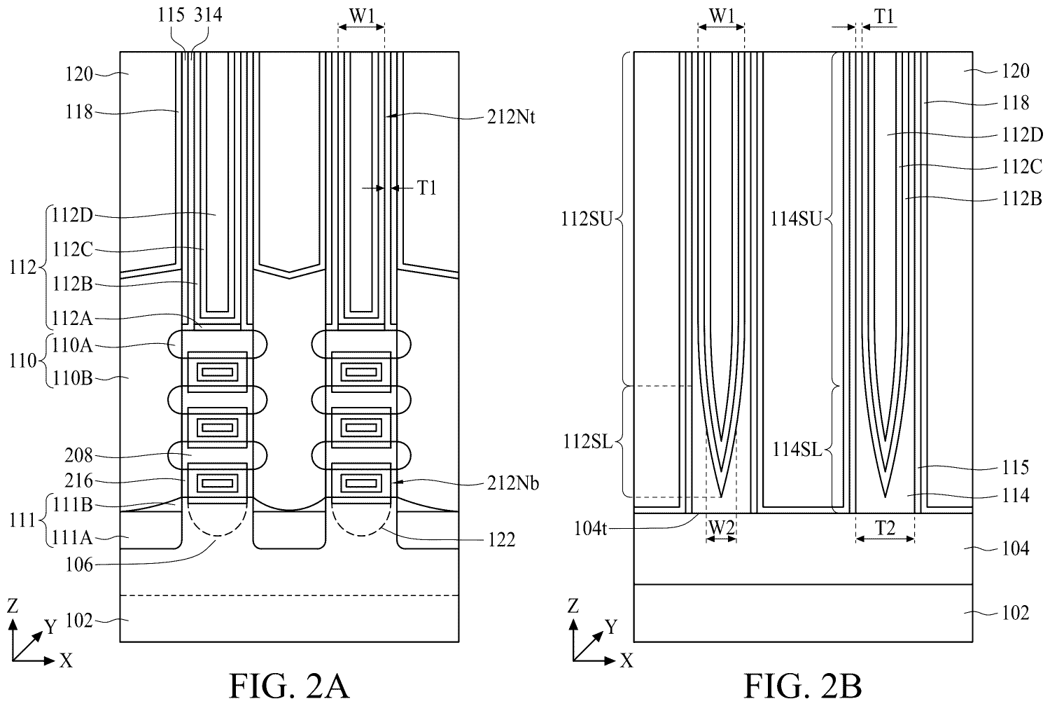

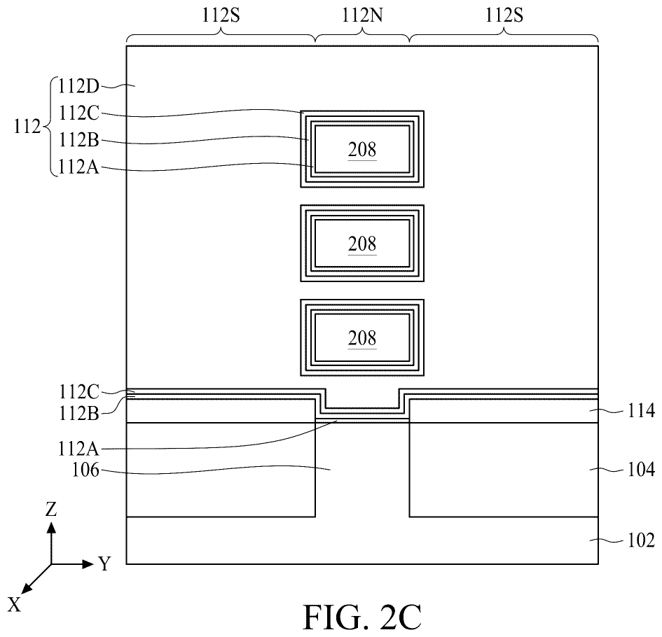

FIG. 1A illustrates an isometric view of a semiconductor device 100, which can represent a GAA FET 100, according to some embodiments. FIG. 1B illustrates a top-down view of GAA FET 100, according to some embodiments. FIGS. 2A, 3A, and 4A illustrate different cross-sectional views of GAA FET 100, along line A-A of FIGS. 1A and 1B, with additional structures that are not shown in FIGS. 1A and 1B for simplicity, according to some embodiments. FIGS. 2B, 3B, and 4B illustrate different cross-sectional views of GAA FET 100, along line B-B of FIGS. 1A and 1B, with additional structures that are not shown in FIGS. 1A and 1B for simplicity, according to some embodiments. FIGS. 2C, 3C, and 4C illustrate different cross-sectional views of GAA FET 100, along line C-C of FIGS. 1A and 1B, with additional structures that are not shown in FIGS. 1A and 1B for simplicity, according to some embodiments. The discussion of elements in FIGS. 1A, 1B, 2A-2C, 3A-3C, and 4A-4C with the same annotations applies to each other, unless mentioned otherwise.

Referring to FIGS. 1A, 1B, and 2A-2C, in some embodiments, GAA FET 100 can include (i) a substrate 102, (ii) STI regions 104 disposed on substrate 102, (iii) fin-shaped base structures 106 (also referred to as a “sheet base 106” or a “fin base 106”) disposed on substrate 102, (iv) nanostructured channel regions 208 disposed on base structure 106, (v) S/D regions 110 disposed adjacent to nanostructured channel regions 208, (vi) isolation structures 111, (vii) gate structures 112 (also referred to as “GAA structures 112”) surrounding nanostructured channel regions 208, (viii) outer gate spacers 114, (ix) barrier layer 115, (x) inner gate spacers 216, (xi) etch stop layers (ESLs) 118 disposed directly on S/D regions 110, and (xii) interlayer dielectric (ILD) layers 120 disposed directly on ESLs 118. Each of S/D regions 110 may refer to a source or a drain, individually or collectively dependent upon the context. Barrier layers 115, ESLs 118, and ILD layers 120 are not shown in FIG. 1B for simplicity.

In some embodiments, substrate 102 can be a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic). In some embodiments, STI regions 104 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ). In some embodiments, base structures 106 can include a material similar to substrate 102. Base structures 106 can have elongated sides extending along an X-axis.

In some embodiments, nanostructured channel regions 208 can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. Nanostructured channel regions 208 can include semiconductor materials similar to or different from substrate 102. In some embodiments, nanostructured channel regions 208 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 208 can have a thickness of about 3 nm to about 15 nm along a Z-axis. Though three nanostructured channel regions 208 are shown under each of gate structures 112, GAA FET 100 can have any number of nanostructured channel regions 208. Though rectangular cross-sections of nanostructured channel regions 208 are shown, nanostructured channel regions 208 can have cross-sections of other geometric shapes (e.g., circular, elliptical, triangular, or polygonal).

In some embodiments, S/D region 110 can be disposed above base structure 106 and can be electrically isolated from base structure 106 by isolation structure 111. In some embodiments, each S/D region 110 can include S/D sub-regions 110A and 110B. S/D sub-regions 110A can be disposed directly on and can be epitaxially grown on sidewalls of nanostructured channel regions 208. In some embodiments, each S/D sub-region 110A can have a D-shaped cross-sectional profile and a curved sidewall in contact with S/D sub-region 110B. The number of S/D sub-regions 110A in each S/D region 110 can be equal to the number of nanostructured channel regions 208 facing each S/D region 110. For example, as shown in FIG. 2A, each S/D region 110 includes six S/D sub-regions 110A, which is equal to the six nanostructured channel regions 208 facing each S/D region 110.

In some embodiments, each S/D sub-region 110B can include (i) first portions disposed directly on and epitaxially grown on S/D sub-regions 110A, and (ii) second portions disposed directly on sidewalls of inner gate spacers 216 and between adjacent S/D sub-regions 110A. The second portions of S/D sub-regions 110B can be formed by the merging of adjacent first portions of S/D sub-regions 110B. In some embodiments, an air gap (not shown) can be present between the sidewalls of inner gate spacers 216 and the second portion of S/D sub-regions 110B.

In some embodiments, for n-type GAA FET 100, S/D sub-regions 110A and 110B can include epitaxially-grown Si without any Ge atoms and can differ from each other based on n-type dopant (e.g., phosphorus atoms) concentrations. For example, S/D sub-regions 110B can have an n-type dopant concentration higher than that in S/D sub-regions 110A. A higher dopant concentration in S/D sub-regions 110B can reduce contact resistance between S/D regions 110 and S/D contact structures (not shown). In some embodiments, S/D sub-regions 110A can be undoped. In some embodiments, S/D sub-regions 110B can include a phosphorus dopant concentration of about 1×10²¹ atoms/cm³ to about 4×10²¹ atoms/cm³.

In some embodiments, for p-type GAA FET 100, S/D sub-regions 110A can include epitaxially-grown Si without any Ge atoms and S/D sub-regions 110B can include epitaxially-grown SiGe. In some embodiments, S/D sub-regions 110B can include a Ge atom concentration of about 45 atomic % to about 60 atomic % with any remaining atomic % being Si atoms. In some embodiments, for p-type GAA FET 100, S/D sub-regions 110A and 110B can differ from each other based on p-type dopant (e.g., boron atoms) concentrations. For example, S/D sub-regions 110B can have a p-type dopant concentration higher than that in S/D sub-regions 110A. In some embodiments, S/D sub-regions 110A can be undoped. In some embodiments, S/D sub-regions 110B can include a boron dopant concentration of about 8×10²⁰ atoms/cm³ to about 3×10²¹ atoms/cm³.

In some embodiments, isolation structures 111 can be disposed under S/D regions 110 and in recessed regions of base structure 106. The recessed region in base structure 106 can be formed during the formation of S/D regions 110, as described in detail below. Isolation structures 111 can prevent the epitaxial growth of S/D regions 110 on base structure 106 and prevent the diffusion of dopants from S/D region 110 to base structure 106, thus preventing current leakage between adjacent S/D regions 110 and short channel effects in GAA FET 100. In some embodiments, each isolation structure 111 can include an undoped semiconductor layer 111A and a dielectric layer 111B.

In some embodiments, undoped semiconductor layer 111A can be disposed in the recessed region of base structure 106. In some embodiments, undoped semiconductor layer 110A can include undoped silicon or other suitable undoped semiconductor material. In some embodiments, undoped semiconductor layer 111A can extend a distance of about 20 nm to about 40 nm into base structure 106. In some embodiments, if the distance is below about 20 nm, undoped semiconductor layer 111A may not adequately prevent the diffusion of dopants from S/D regions 110 to base structure 106. On the other hand, if the distance is above about 40 nm, the processing time (e.g., etching time, deposition time) for forming undoped semiconductor layer 111A increases, and consequently increases the manufacturing cost of GAA FET 100.

In some embodiments, dielectric layer 111B can be disposed directly on undoped semiconductor layer 111A and along sidewalls of the recessed region in base structure 106. In some embodiments, each dielectric layer 111B can include a nitride material, such as SiN, SiON, SiCON, and SiCN. In some embodiments, each dielectric layer 111B can include a silicon-rich dielectric material. In some embodiments, the silicon-rich dielectric material can include (i) silicon-rich nitride (SiₓN_{y}) with a concentration of silicon atoms higher than the concentrations of nitrogen atoms, (ii) silicon-rich oxynitride (SiₓO_{y}N_{z}) with a concentration of silicon atoms higher than the concentrations of oxygen atoms and nitrogen atoms, (iii) silicon-rich oxycarbide (SiₓO_{y}C_{z}) with a concentration of silicon atoms higher than the concentrations of oxygen atoms and carbon atoms, (iv) silicon-rich oxycarbon nitride (Si_{w}OₓC_{y}N_{z}) with a concentration of silicon atoms higher than the concentrations of oxygen atoms, carbon atoms, and nitrogen atoms, (v) silicon-rich boron oxynitride (Si_{w}BₓO_{y}N_{z}) with a concentration of silicon atoms higher than the concentrations of oxygen atoms, boron atoms, and nitrogen atoms, (vi) silicon-rich boron oxycarbide (Si_{w}BₓO_{y}C_{z}) with a concentration of silicon atoms higher than the concentrations of oxygen atoms, boron atoms, and carbon atoms, or (vii) other suitable silicon-rich nitride- or carbide-based dielectric materials. The silicon-rich dielectric material of dielectric layer 111B can provide a high etch resistance to dielectric layer 111B during the formation of dielectric layer 111B.

Each of gate structures 112 can be a multi-layered structure and can include (i) an interfacial oxide (IL) layer 112A, (ii) a high-k (HK) gate dielectric layer 112B, (iii) a work function metal (WFM) layer 112C, and (iv) a gate metal fill layer 112D. In some embodiments, IL layer 112A can be disposed directly on topmost nanostructured channel regions 208. In some embodiments, IL layer 112A can include SiO₂, SiGeOₓ, or germanium oxide (GeOₓ) and can have a thickness of about 0.5 nm to about 1 nm. In some embodiments, HK gate dielectric layer 112B can be disposed directly on IL layer 112A and can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of HK gate dielectric layer 112B can be in contact with sidewalls of outer gate spacers 114.

WFM layer 112C can be disposed on HK gate dielectric layer 112B. In some embodiments, WFM layer 112C can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for p-type GAA FET 100. In some embodiments, WFM layer 112C can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type GAA FET 100. Gate metal fill layer 112D can be disposed on WFM layer 112C. In some embodiments, gate metal fill layer 112D can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Each of gate structures 112 can have a pair of outer gate portions 112S (shown in FIGS. 1A, 1B, 2B, and 2C; not visible in cross-sectional view of FIG. 2A) and an inner gate portion 112N (shown in FIGS. 1A, 1B, 2A, and 2C; not visible in cross-sectional view of FIG. 2B) between the pair of outer gate portions 112S. In some embodiments, each of outer gate portions 112S can be disposed on STI region 104, but not in direct contact with STI region 104. Outer gate portion 112S can be separated from STI region 104 by a portion of outer gate spacer 114. Each of outer gate portions 112S can have an upper gate portion 112SU and a lower gate portion 112SL. In some embodiments, each of upper gate portions 112SU can have (i) a rectangular cross-sectional profile along an X-axis (shown in FIG. 2B), (ii) substantially linear sidewalls, and (iii) a width W1 of about 9 nm to about 12 nm. In some embodiments, each of lower gate portions 112SL can have (i) a tapered cross-sectional profile (e.g., a V-shaped cross-sectional profile) along an X-axis, (ii) sloped sidewalls, (iii) an angle of about 70 degrees to about 80 degrees between the sloped sidewall and a top surface 104t of STI region 104, and (iv) a width W2 of about 5 nm to about 8 nm in a middle region of lower gate portion 112SL. In some embodiments, the portions of HK gate dielectric layers 112B in upper gate portions 112SU can have substantially linear sidewalls and the portions of HK gate dielectric layers 112B in lower gate portions 112SL can have sloped sidewalls and V-shaped cross-sectional profiles along an X-axis.

In some embodiments, each of inner gate portions 112N can have a top gate portion 212Nt and a bottom gate portion 212Nb, as shown in FIG. 2A. Top gate portions 212Nt can be disposed on and in contact with topmost nanostructured channel regions 208. In some embodiments, each of top gate portions 212Nt can have (i) a rectangular cross-sectional profile along an X-axis, (ii) substantially linear sidewalls, and (iii) width W1 of about 9 nm to about 12 nm. Bottom gate portions 212Nb can be disposed between bottommost nanostructured channel regions 208 and base structure 106. In some embodiments, each of bottom gate portions 212Nb can have (i) a rectangular cross-sectional profile along an X-axis and (ii) a substantially linear bottom surface in contact with a top surface of base structure 106. The substantially linear profiles of the bottom surfaces of bottom gate portions 212Nb can depend on the structural profiles of lower gate portions 112SL.

The formation of lower gate portions 112SL with tapered cross-sectional profiles and separated from STI region 104 prevents the formation of trenches in base structure 106 (e.g., trenches 122 shown with dotted line in FIG. 2A) during the formation of gate structures 112 in a gate replacement process, as discussed in detail below. Trenches, such as trenches 122 in base structures of other GAA FETs, are formed during the formation of gate portions with non-tapered cross-sectional profiles (e.g., rectangular cross-sectional profiles) on STI regions. Preventing the formation of such trenches in the regions of base structure 106 underlying nanostructured channel regions 208 can prevent bottom gate portions 212Nb from extending into base structure 106, which reduces the spacing between gate structure 112 and S/D region 110 and increases the parasitic capacitance of GAA FET 100. Thus, the formation of lower gate portions 112SL with tapered cross-sectional profiles and separated from STI region 104 facilitates the formation of the substantially linear profiles of the bottom surfaces of bottom gate portions 212Nb.

In some embodiments, the portions of HK gate dielectric layers 112B in top gate portions 212Nt can have U-shaped cross-sectional profiles along an X-axis. In some embodiments, the portions of HK gate dielectric layers 112B in bottom gate portions 212Nb can have rectangular ring-shaped cross-sectional profiles along an X-axis. In some embodiments, the portions of HK gate dielectric layers 112B in inner gate portions 212Nb can have rectangular ring-shaped cross-sectional profiles along a Y-axis. In some embodiments, the portions of HK gate dielectric layers 112B on base structure 106 in inner gate portions 112N can be disposed at a lower surface plane than the portions of HK gate dielectric layers 112B disposed on STI region 104 in outer gate portions 112S, as shown in FIG. 2C. In some embodiments, the top surfaces of the regions of base structure 106 underlying nanostructured channel regions 208 and top surfaces 104t of STI regions 104 can be substantially coplanar with each other, as shown in FIG. 2C.

Outer gate spacers 114 electrically isolate gate structures 112 from adjacent S/D regions 110 and other adjacent structures, such as S/D contact structures (not shown). In some embodiments, each of outer gate spacers 114 can include a dielectric material, such as SiO₂, SiN, SiON, SiCN, and SiOCN. In some embodiments, each of outer gate spacers 114 can have outer sidewalls with substantially linear profiles facing away from gate structure 112 and an inner sidewall with a V-shaped cross-sectional profile facing toward gate structure 112. In some embodiments, each of outer gate spacers 114 can have a pair of outer spacer portions 114S (shown in FIGS. 1A, 1B, 2B, and 2C; not visible in cross-sectional view of FIG. 2A) and an inner spacer portion 114N (shown in FIGS. 1A, 1B, 2A, and 2C; not visible in cross-sectional view of FIG. 2B) between the pair of outer spacer portions 112S.

In some embodiments, each of inner spacer portions 114N can be disposed along sidewalls of top gate portion 212Nt and on topmost nanostructured channel region 208 and can have a thickness T1 of about 6 nm to about 8 nm. In some embodiments, each of outer spacer portions 114S can be disposed directly on STI region 104 and can surround outer gate portion 112S. Each of outer spacer portions 114S can have an upper spacer portion 114SU and a lower spacer portion 114SL. In some embodiments, each of upper spacer portions 114SU can have (i) a rectangular cross-sectional profile along an X-axis (shown in FIG. 2B), (ii) substantially linear sidewalls disposed along sidewalls of upper gate portion 112SU, and (iii) thickness T1 of about 6 nm to about 8 nm. In some embodiments, each of lower spacer portions 114SL can have (i) substantially linear outer sidewalls facing away from lower gate portion 112SL, (ii) sloped inner sidewalls facing towards and in contact with lower gate portion 112SL, (iii) a thickness T2 of about 30 nm to about 35 nm. Such profiles and dimensions of outer spacer portions 114S facilitate the formation of lower gate portions 112SL with tapered cross-sectional profiles, as discussed in detail below.

Inner gate spacers 216 can electrically isolate gate portions between nanostructured channel regions 208 and bottom gate portions 212Nb from adjacent S/D regions 110. In some embodiments, each of inner gate spacers 216 can have a height of about 3 nm to about 20 nm and a thickness of about 1 nm to about 10 nm. Within these ranges of height and thickness, inner gate spacers 216 can adequately electrically isolate gate portions from adjacent S/D regions 110 without compromising the device size and manufacturing cost.

In some embodiments, ESLs 118 can be disposed directly on S/D regions 110. In some embodiments, ESLs 118 can have a dielectric constant of about 4 to about 7 and can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 120 can be disposed directly on ESLs 118. In some embodiments, ILD layers 120 can include an insulating material, such as SiO₂, SiN, SiON, SiCN, and SiOCN.

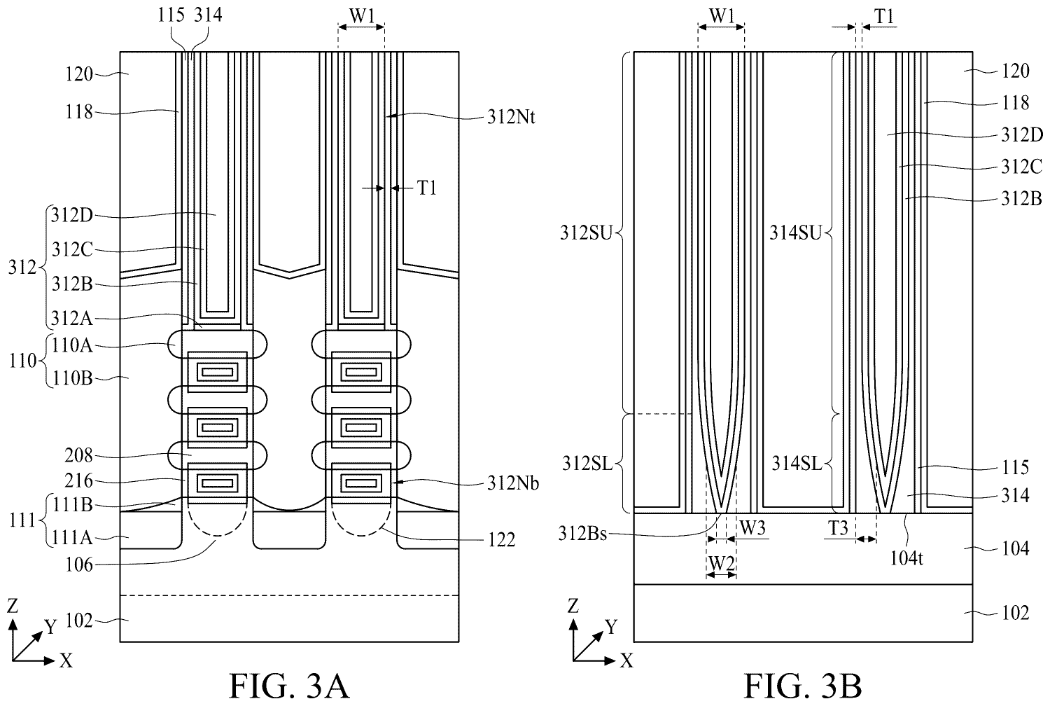

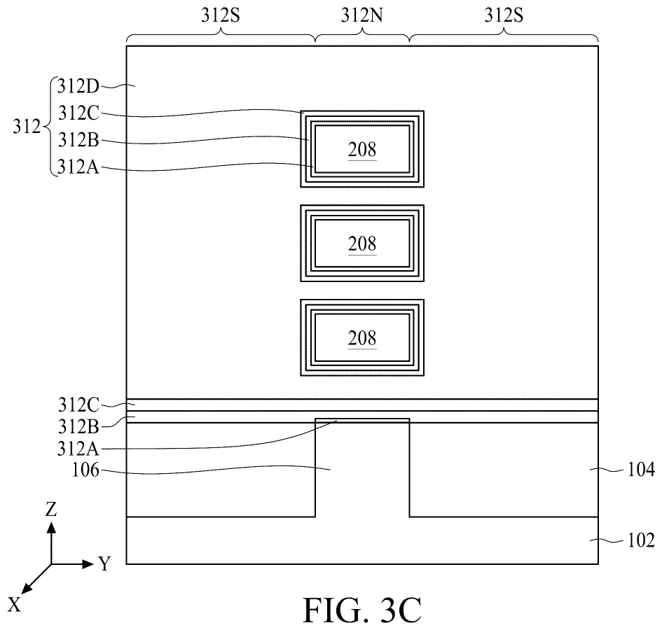

Referring to FIGS. 3A-3C, in some embodiments, GAA FET 100 can have gate structures 312 and outer gate spacers 314, instead of gate structures 112 and outer gate spacers 114. The discussion of gate structures 112 and outer gate spacers 114 applies to gate structures 312 and outer gate spacers 314, unless mentioned otherwise. Similar to gate structures 112, each of gate structures 312 can be a multi-layered structure and can include (i) an IL layer 312A, (ii) a HK gate dielectric layer 312B, (iii) a WFM layer 312C, and (iv) a gate metal fill layer 312D. The discussion of IL layer 112A, HK gate dielectric layer 112B, WFM layer 112C, and gate metal fill layer 112D applies to IL layer 312A, HK gate dielectric layer 312B, WFM layer 312C, and gate metal fill layer 312D, respectively, unless mentioned otherwise.

Each of gate structures 312 can have a pair of outer gate portions 312S and an inner gate portion 312N between the pair of outer gate portions 312S. In some embodiments, each of outer gate portions 312S can be disposed directly on STI region 104. Each of outer gate portions 312S can have an upper gate portion 312SU and a lower gate portion 312SL. In some embodiments, each of upper gate portions 312SU can have (i) a rectangular cross-sectional profile along an X-axis (shown in FIG. 3B), (ii) substantially linear sidewalls, and (iii) width W1 of about 9 nm to about 12 nm. In some embodiments, each of lower gate portions 312SL can have (i) a tapered cross-sectional profile along an X-axis, (ii) sloped sidewalls, (iii) an angle of about 70 degrees to about 80 degrees between the sloped sidewall and top surface 104t of STI region 104, (iv) a substantially linear bottom surface 312Bs in contact with top surface 104t of STI region 104, (v) width W2 of about 5 nm to about 8 nm in a middle region of lower gate portion 312SL, and (vi) a width W3 of about 0 nm to about 3 nm of bottom surface 312Bs. In some embodiments, the portions of HK gate dielectric layers 312B in upper gate portions 312SU can have substantially linear sidewalls and the portions of HK gate dielectric layers 312B in lower gate portions 312SL can have sloped sidewalls and substantially linear bottom surface in contact with top surface 104t of STI region 104.

In some embodiments, each of inner gate portions 312N can have a top gate portion 312Nt and a bottom gate portion 312Nb. The discussion of top gate portion 212Nt and bottom gate portion 212Nb applies to top gate portion 312Nt and bottom gate portion 312Nb, unless mentioned otherwise. Similar to bottom gate portion 212Nb, the substantially linear profiles of the bottom surfaces of bottom gate portions 312Nb can depend on the structural profiles of lower gate portions 312SL. Even though lower gate portions 312SL are in contact with STI regions 104, unlike lower gate portions 112SL, the tapered cross-sectional profiles of lower gate portions 312SL can prevent the formation of trenches in base structure 106 (e.g., trenches 122 shown with dotted line in FIG. 3A) during the formation of gate structures 312 in the gate replacement process, as discussed in detail below. In some embodiments, gate structures 312 with lower gate portions 312SL in contact with STI region 104 can be formed in GAA FET 100, instead of gate structures 112, to reduce etching time during the gate replacement process, thus reducing manufacturing cost of GAA FET 100, as discussed in detail below.

In some embodiments, the portions of HK gate dielectric layers 312B on base structure 106 in inner gate portions 312N and on STI region 104 in outer gate portions 312S can be substantially coplanar with each other, as shown in FIG. 3C. In some embodiments, the top surfaces of the regions of base structure 106 underlying nanostructured channel regions 208 and top surfaces 104t of STI regions 104 can be substantially coplanar with each other, as shown in FIG. 3C.

In some embodiments, each of outer gate spacers 314 can have a pair of outer spacer portions 314S and an inner spacer portion 314N between the pair of outer spacer portions 312S. In some embodiments, each of inner spacer portions 314N can be disposed along sidewalls of top gate portion 312Nt and on topmost nanostructured channel region 208 and can have thickness T1 of about 6 nm to about 8 nm. In some embodiments, each of outer spacer portions 314S can be disposed directly on STI region 104 and along sidewalls of outer gate portion 312S. Each of outer spacer portions 314S can have an upper spacer portion 314SU and a lower spacer portion 314SL. In some embodiments, each of upper spacer portions 314SU can have (i) a rectangular cross-sectional profile along an X-axis (shown in FIG. 3B), (ii) substantially linear sidewalls disposed along sidewalls of upper gate portion 312SU, and (iii) thickness T1 of about 6 nm to about 8 nm. In some embodiments, each of lower spacer portions 314SL can have (i) substantially linear outer sidewalls facing away from lower gate portion 312SL, (ii) sloped inner sidewalls facing towards and in contact with lower gate portion 312SL, (iii) a thickness T3 of about 15 nm to about 17 nm. Such profiles and dimensions of outer spacer portions 314S facilitate the formation of lower gate portions 312SL with tapered cross-sectional profiles, as discussed in detail below.

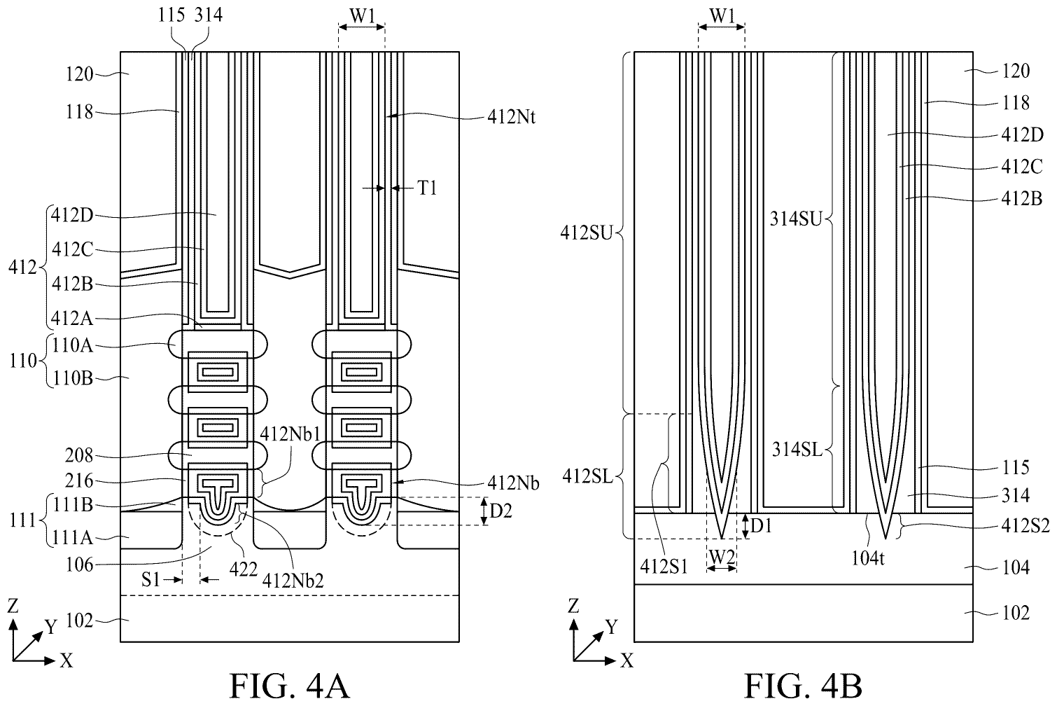

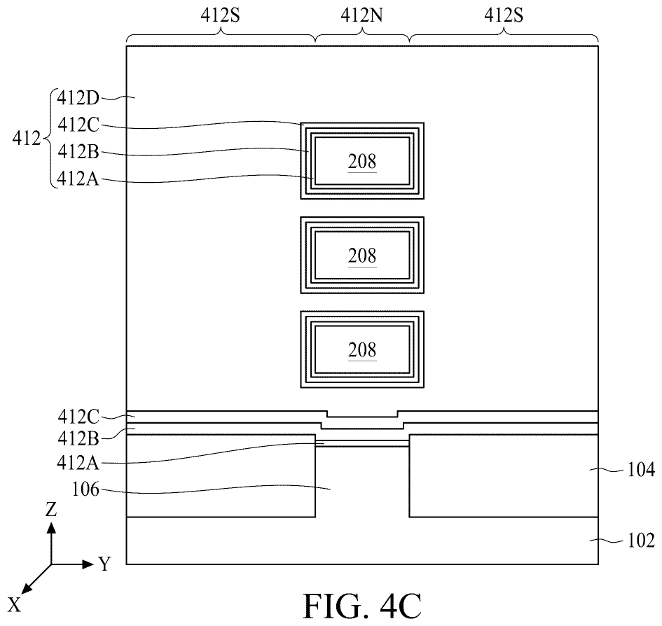

Referring to FIGS. 4A-4C, in some embodiments, GAA FET 100 can have gate structures 412, instead of gate structures 112 or 312. The discussion of gate structures 112 applies to gate structures 412 and outer gate spacers 314, unless mentioned otherwise. Similar to gate structures 112, each of gate structures 412 can be a multi-layered structure and can include (i) an IL layer 412A, (ii) a HK gate dielectric layer 412B, (iii) a WFM layer 412C, and (iv) a gate metal fill layer 412D. The discussion of IL layer 112A, HK gate dielectric layer 112B, WFM layer 112C, and gate metal fill layer 112D applies to IL layer 412A, HK gate dielectric layer 412B, WFM layer 412C, and gate metal fill layer 412D, respectively, unless mentioned otherwise.

Each of gate structures 412 can have a pair of outer gate portions 412S and an inner gate portion 412N between the pair of outer gate portions 412S. In some embodiments, each of outer gate portions 412S can extend a distance D1 into STI region 104, as shown in FIG. 4B. Each of outer gate portions 412S can have an upper gate portion 412SU and a lower gate portion 412SL. In some embodiments, each of upper gate portions 412SU can have (i) a rectangular cross-sectional profile along an X-axis (shown in FIG. 4B), (ii) substantially linear sidewalls, and (iii) width W1 of about 9 nm to about 12 nm. In some embodiments, each of lower gate portions 412SL can have a V-shaped cross-sectional profile along an X-axis, which extends distance D1 into STI region 104. In some embodiments, each of lower gate portions 412SL can have (i) a first portion 412S1 with a tapered cross-sectional profile along an X-axis, which is disposed on top surface 104t of STI region 104, (ii) a second portion 412S2 with a V-shaped cross-sectional profile along an X-axis, which extends distance D1 of about 2 nm to about 4 nm below top surface 104t of STI region 104, (iii) sloped sidewalls of first and second portions 412S1 and 412S2, (iv) an angle of about 70 degrees to about 80 degrees between the sloped sidewalls and top surface 104t of STI region 104, and (iv) width W2 of about 5 nm to about 8 nm in a middle region of lower gate portion 412SL. In some embodiments, the portions of HK gate dielectric layers 412B in upper gate portions 412SU can have substantially linear sidewalls and the portions of HK gate dielectric layers 412B in lower gate portions 412SL can have sloped sidewalls and can extend distance D1 into STI region 104.

In some embodiments, each of inner gate portions 412N can have a top gate portion 412Nt and a bottom gate portion 412Nb. The discussion of top gate portion 212Nt applies to top gate portion 412Nt, unless mentioned otherwise. Unlike bottom gate portions 212Nb, each of bottom gate portions 412Nb can have (i) a first portion 412Nb1 with rectangular cross-sectional profile along an X-axis, which is disposed on top surface of base structure 106, and (ii) a second portion 412Nb2 with a U-shaped cross-sectional profile (shown in FIG. 4A) or a V-shaped cross-sectional profile (not shown) along an X-axis, which extends a distance D2 of about 2 nm to about 4 nm below top surface of base structure 106. In some embodiments, distance D2 can be equal to or greater than distance D1. The structural profiles of second portions 412Nb2 can depend on the structural profiles of lower gate portions 412SL.

Due to the formation of lower gate portions 412SL with tapered cross-sectional profiles, second portions 412Nb2 can be formed in base structure 106 with narrower cross-sectional profiles along an X-axis (shown in FIG. 4A) than gate portions (e.g., gate portions 422 shown in dotted lines in FIG. 4A) formed in base structures during the formation of gate structures with non-tapered cross-sectional profiles in other GAA FETs. The narrower cross-sectional profiles of second portions 412Nb2 can result in horizontal spacings S1 of about 9 nm to about 14 nm between second portions 412Nb2 and adjacent S/D regions, which are greater than horizontal spacings of about 3 nm to about 8 nm achieved between gate portions 422 and S/D regions in other GAA FETs. Such increase in horizontal spacings S1 can lead to the reduction of parasitic capacitance in GAA FET 100.

In addition to the narrower cross-sectional profiles, second portions 412Nb2 in base structure 106 can be formed with shallower depth profiles than that of gate portions 422 due to the formation of lower gate portions 412SL with tapered cross-sectional profiles. Second portions 412Nb2 extend distance D2 of about 2 nm to about 4 nm into base structure 106, whereas gate portions 422 extend a distance of about 8 nm to about 10 nm into base structures of other GAA FETs. Thus, with the use gate structures 412 having tapered gate portions (e.g., lower gate portions 412SL) on STI regions 104, the volume of gate portions (e.g., second portions 412Nb2) in base structure 106 can be reduced, consequently reducing parasitic capacitance of GAA FET 100. In some embodiments, gate structures 412 with lower gate portions 412SL extending into STI region 104 can be formed in GAA FET 100, instead of gate structures 112 or 312, as a consequence of forming gate structures 412 with higher aspect ratios than that of gate structures 112 or 312, as discussed in detail below. In some embodiments, the portions IL layer 412A, HK gate dielectric layer 412B, WFM layer 412C, and gate metal fill layer 412D in second portions 412Nb2 can have U-shaped or V-shaped cross-sectional profiles along an X-axis, as shown in FIG. 4A.

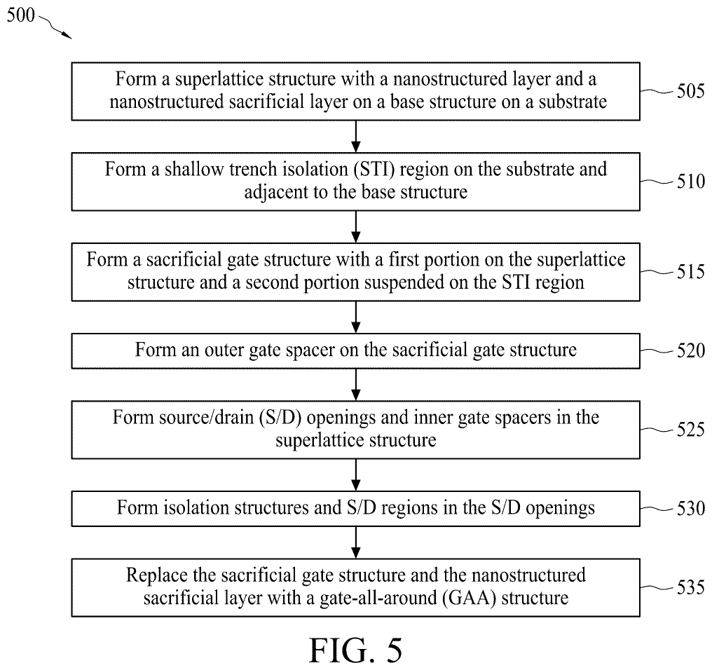

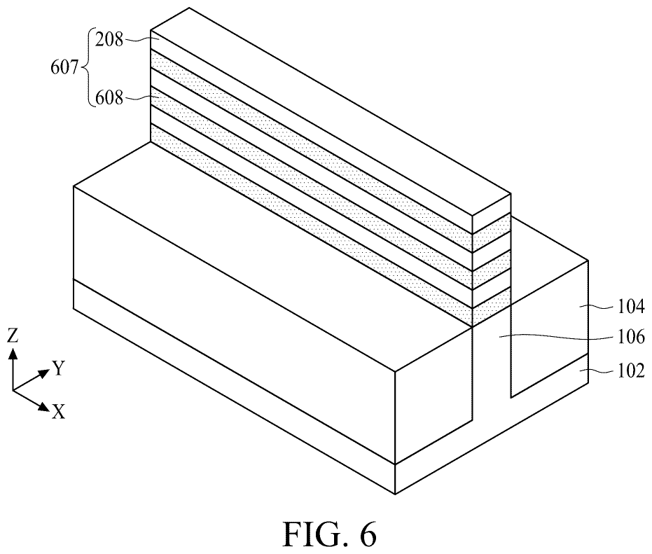

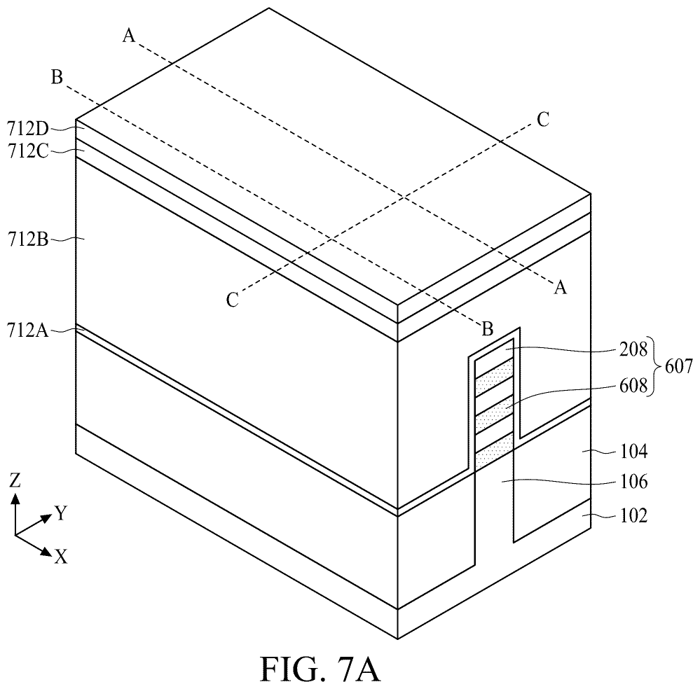

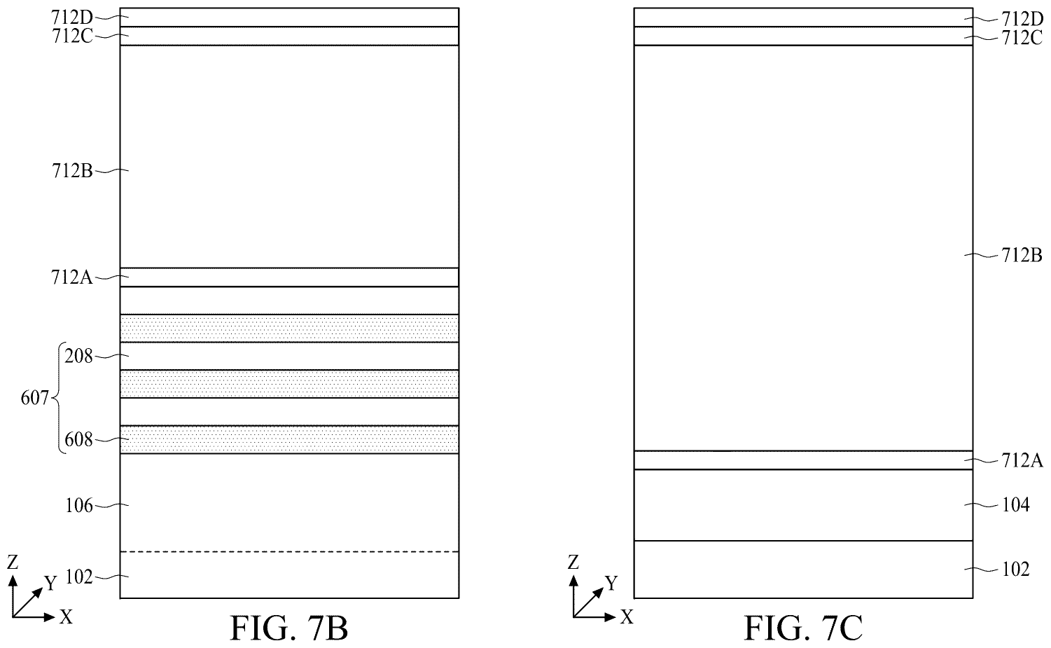

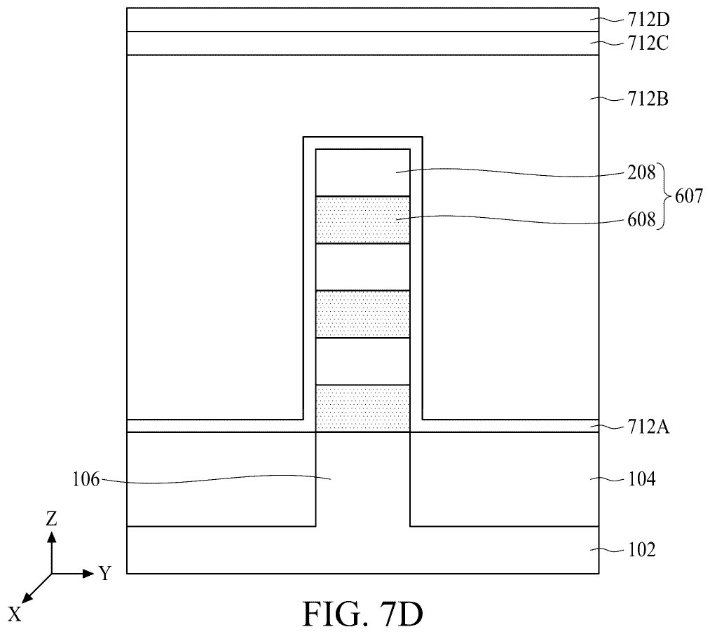

FIG. 5 is a flow diagram of an example method 500 for fabricating GAA FET 100 with the isometric, top-down, and cross-sectional views of FIGS. 1A, 1B, and 2A-2C, according to some embodiments. For illustrative purposes, the operations illustrated in FIG. 5 will be described with reference to the example fabrication process for fabricating GAA FET 100 as illustrated in FIGS. 6, 7A-7D, 8A-8D, 9A-9D, 10A-10D, 11A-11D, 12A-12C, 13A-13C, 14A-14C, and 15A-15C. FIGS. 6, 7A, 8A, 9A, 10A, and 11A are isometric views of GAA FET 100 at various stages of its fabrication, according to some embodiments. FIGS. 7B, 8B, 9B, 10B, 11B, 12A, 13A, 14A, and 15A are cross-sectional views of GAA FET 100, along lines A-A of FIGS. 1A, 1B, 7A, 8A, 9A, 10A, and 11A, at various stages of its fabrication, according to some embodiments. FIGS. 7C, 8C, 9C, 10C, 11C, 12B, 13B, 14B, and 15B are cross-sectional views of GAA FET 100, along lines B-B of FIGS. 1A, 1B, 7A, 8A, 9A, 10A, and 11A, at various stages of its fabrication, according to some embodiments. FIGS. 7D, 8D, 9D, 10D, 11D, 12C, 13C, 14C, and 15C are cross-sectional views of v, along lines C-C of FIGS. 1A, 1B, 7A, 8A, 9A, 10A, and 11A, at various stages of its fabrication, according to some embodiments. Operations can be performed in a different order or not performed depending on specific applications. It should be noted that method 500 may not produce a complete GAA FET 100. Accordingly, it is understood that additional processes can be provided before, during, and after method 500, and that some other processes may only be briefly described herein. The discussion of elements in FIGS. 1A, 1B, 2A-2C, 6, 7A-7D, 8A-8D, 9A-9D, 10A-10D, 11A-11D, 12A-12C, 13A-13C, 14A-14C, and 15A-15C with the same annotations applies to each other, unless mentioned otherwise.

Referring to FIG. 5, in operation 505, a superlattice structure with a nanostructured layer and a nanostructured sacrificial layer is formed on a base structure on a substrate. For example, as described with reference to FIG. 6, a superlattice structure 607 (also referred to as “a nanosheet stack 607”) is formed on fin-shaped base structure 106, which is formed on substrate 102. Superlattice structure 607 can include nanostructured layers 208 and nanostructured sacrificial layers 608 arranged in an alternating configuration. In some embodiments, nanostructured layers 208 can include Si, and nanostructured sacrificial layers 608 can include SiGe.

Referring to FIG. 5, in operation 510, an STI region is formed on the substrate and adjacent to the base structure. For example, as described with reference to FIG. 6, STI region 104 is formed on substrate 102 and adjacent to base structure 106. In some embodiments, the formation of STI regions 104 can include sequential operations of (i) depositing a dielectric layer (not shown) having the material of STI region 104 on substrate 102 and superlattice structure 607, (ii) performing a chemical mechanical polishing (CMP) process to coplanarize (not shown) top surfaces of the dielectric layer and superlattice structure 607, and (iii) performing an etch process on the dielectric layer to form the structure of FIG. 6. In some embodiments, top surfaces of STI regions 104 and base structure 106 can be substantially coplanar with each other.

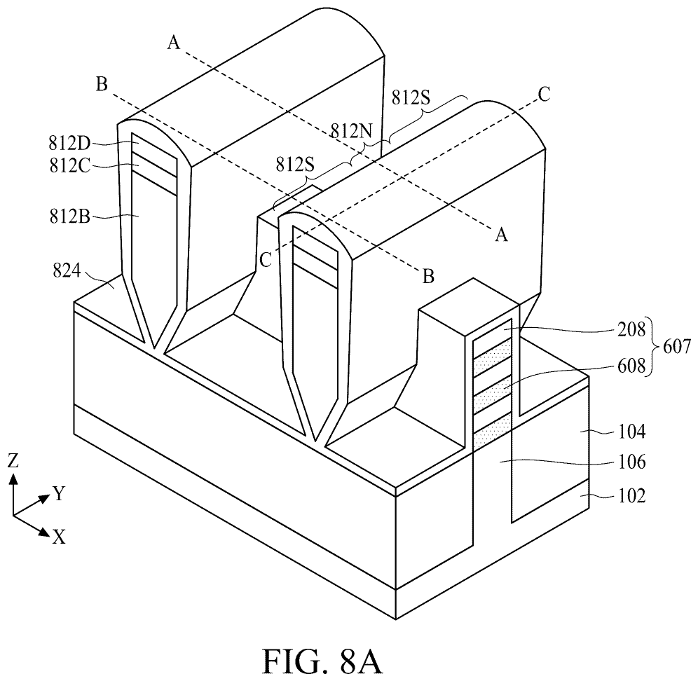

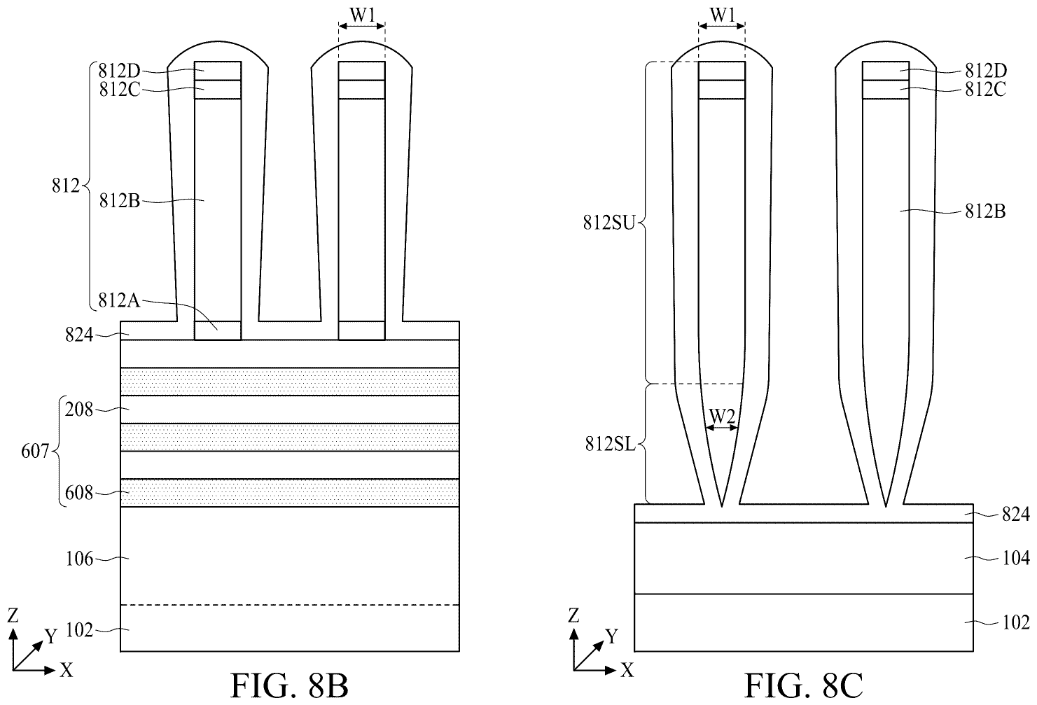

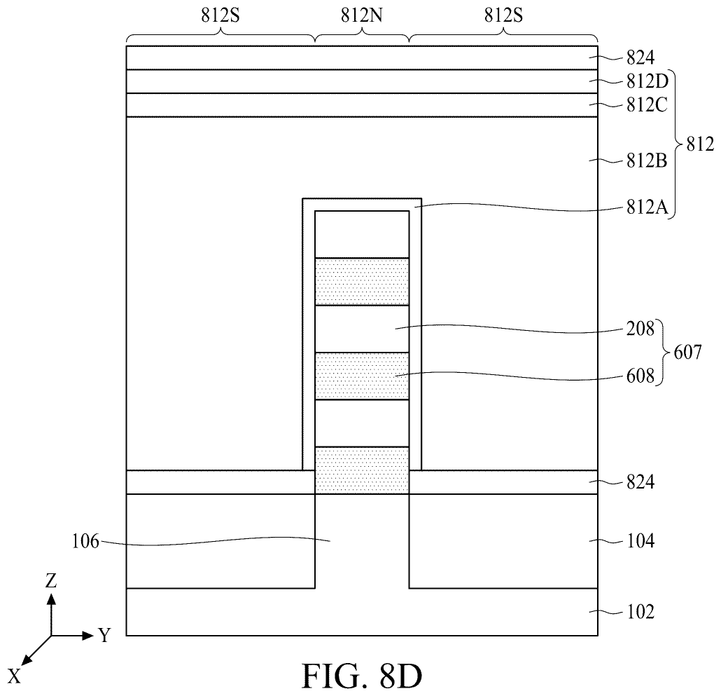

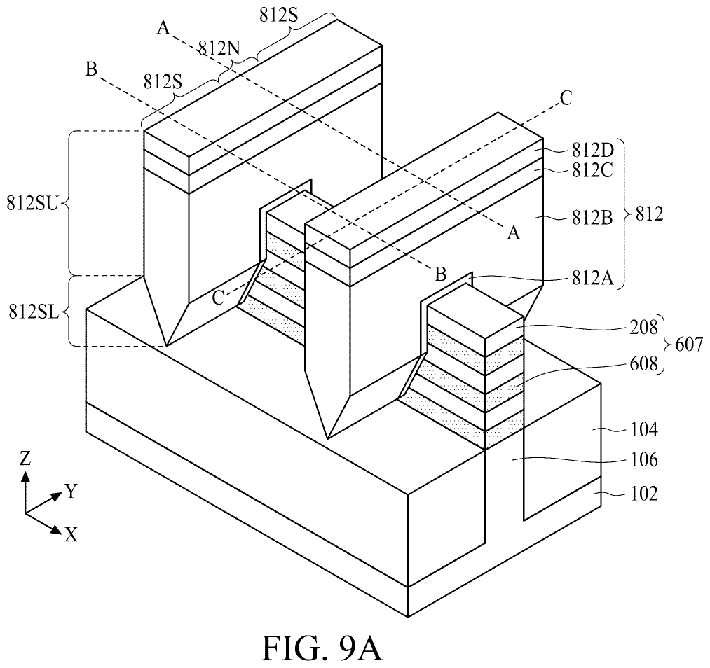

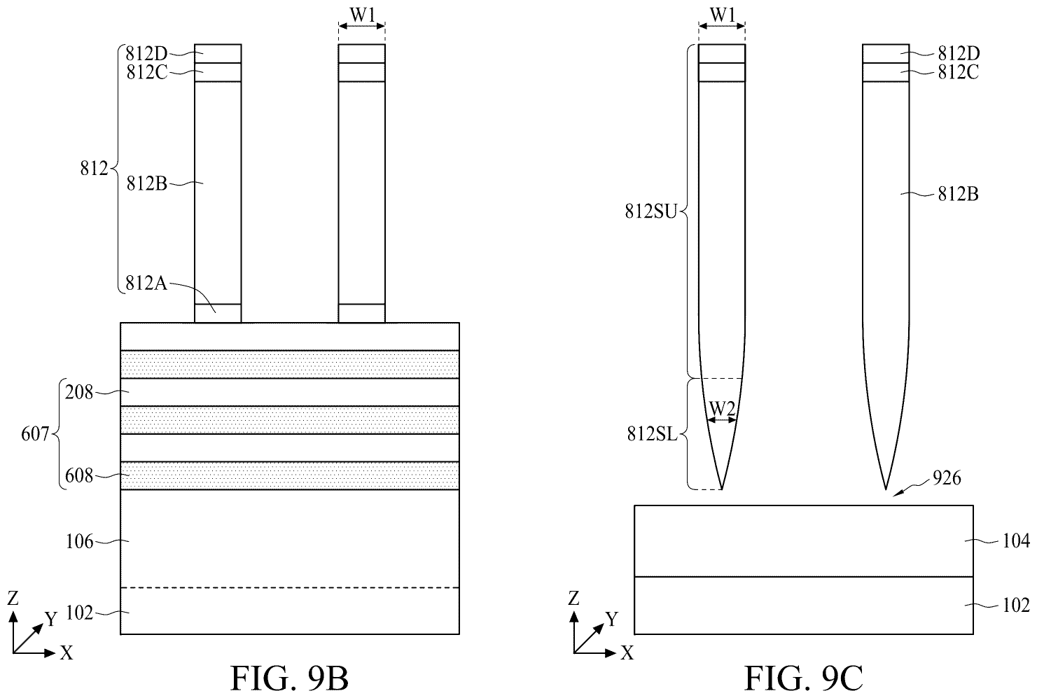

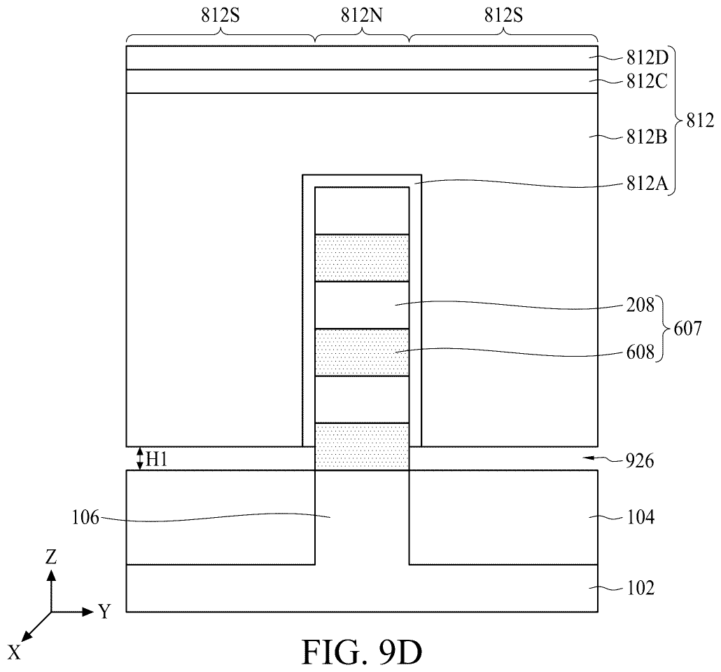

Referring to FIG. 5, in operation 515, a sacrificial gate structure with a first portion on the superlattice structure and a second portion suspended on the STI region is formed. For example, as described with reference to FIGS. 7A-7D, 8A-8D, and 9A-9D, sacrificial gate structures 812 with outer gate portions 812S suspended over STI region 104 and inner gate portion 812N on superlattice structure 607 are formed. In some embodiments, the formation of sacrificial gate structure 812 can include sequential operations of (i) depositing an oxide layer 712A substantially conformally on STI regions 104 and superlattice structure 607 of FIG. 6, as shown in FIGS. 7A-7D, (ii) depositing an amorphous, polycrystalline, or monocrystalline polysilicon layer 712B on oxide layer 712A, as shown in FIGS. 7A-7D, (iii) depositing a nitride mask layer 712C (e.g., SiN layer) on polysilicon layer 712B, as shown in FIGS. 7A-7D, (iv) depositing an oxide mask layer 712D (e.g., SiO₂ layer) on nitride mask layer 712C, as shown in FIGS. 7A-7D, (v) performing a lithographic patterning process (not shown) on the structures of FIGS. 7A-7D, (vi) performing a first etch process on the structures of FIGS. 7A-7D to form sacrificial gate structures 812 having IL layers 812A, polysilicon structures 812B, nitride layers 812C, and oxide layers 812D, and a byproduct layer 824, as shown in FIGS. 8A-8D, and (vii) performing a second etch process (also referred to as a “purging process”) using hydrofluoric (HF) acid gas or solution on the structures of FIGS. 8A-8D to remove byproduct layer 824 and form sacrificial gate structures 812 with outer gate portions 812S suspended over STI regions 104 and inner gate portion 812N directly on superlattice structure 607, as shown in FIGS. 9A-9D.

Referring to FIGS. 8A-8D and 9A-9D, in some embodiments, each of outer gate portions 812S can have (i) an upper gate portion 812SU having a first portion of polysilicon structure 812B, nitride layer 812C, and oxide layer 812D, and (ii) a lower gate portion 812SL having a second portion of polysilicon structure 812B. In some embodiments, the upper portion of polysilicon structure 812B, nitride layer 812C, and oxide layer 812D in each of upper gate portions 812SU can have (i) rectangular cross-sectional profiles along an X-axis, (ii) substantially linear sidewalls, and (iii) widths W1 of about 9 nm to about 12 nm. In some embodiments, the lower portion of polysilicon structure 812B in each of lower gate portions 812SL can have (i) a tapered cross-sectional profile (e.g., a V-shaped cross-sectional profile) along an X-axis, (ii) sloped sidewalls, (iii) an angle of about 70 degrees to about 80 degrees between the sloped sidewall and top surface 104t of STI region 104, and (iv) width W2 of about 5 nm to about 8 nm in a middle region of the lower portion of polysilicon structure 812B. In some embodiments, each of inner gate portions 812N can be disposed on and in contact with topmost nanostructured layer 208 of superlattice structure 607. In some embodiments, each of inner gate portions 812N can have (i) a rectangular cross-sectional profile along an X-axis, (ii) substantially linear sidewalls, and (iii) width W1 of about 9 nm to about 12 nm.

In some embodiments, the deposition of oxide layer 712A in operation of 515 can include exposing the structure of FIG. 6 to a precursor, such as tetraethylorthosilicate (TEOS), in a chemical vapor deposition (CVD) process at a temperature of about 650° C. to about 750° C. to deposit oxide layer 712A (e.g., SiO₂) of about 2 nm to about 4 nm.

In some embodiments, after the first etch process in operation of 515, portions of oxide layer 712A under outer gate portions 812S can be completely removed as shown in FIGS. 8A, 8C, 8D, while portions of oxide layer 712A at the interfaces between polysilicon structure 812B and superlattice structure 607 are retained to form IL layers 812A, as shown in FIGS. 8B and 8D. In some embodiments, during the first etch process byproduct layer 824 can be formed on sacrificial gate structures 812 and exposed surfaces of superlattice structure 607 and STI regions 104, as shown in FIGS. 8A-8D. In some embodiments, byproduct layer 824 can be formed as a result of etch byproducts produced from reactions between the etched off materials of oxide layer 712A, polysilicon layer 712B, nitride mask layer 712C, oxide mask layer 712D, and the gas mixture used in the first etch process. In some embodiments, byproduct layer 824 can include silicon monoxide (SiO), a byproduct of SiO and chlorine (Cl), a byproduct of SiO and nitrogen (N), a byproduct of SiO and argon (Ar), and/or a product of SiO and hydrogen bromide (HBr). In some embodiments, after the removal of byproduct layer 824 during the second etch process, a gap 926 having a height H1 of about 2 nm to about 5 nm can be formed between polysilicon structure 812B and STI region 104, as shown in FIGS. 9C and 9D.

In some embodiments, the first etch process can include a plasma etch process using a gas mixture of an etch gas and a dilute carrier gas. In some embodiments, the etch gas can include Cl₂, HBr, difluoromethan (CH₂F₂), fluoroform (CHF₃), carbon tetrafluoride (CF₄), chlorodifluoromethane (CHClF₂), fluoromethan (CH₃F), hexafluorocyclobutene (C₄F₆), boron trichloride (BCl₃), sulfur hexafluoride (SF₆), or hydrogen (H₂). In some embodiments, the carrier gas can include an inert gas, such as Ar, N₂, helium (He), and neon (Ne). In addition, the gas mixture used in the plasma etch process can include a passivation gas. In some embodiments, the passivation gas can include N₂, O₂, CO₂, CH₄, SO2, CO, and/or SiCl4. The passivation gas can be used to vary the etch selectivity of polysilicon layer 712B along the heights of sacrificial gate structures 812 to achieve the cross-sectional profiles of polysilicon structures 812B of FIG. 8C having different widths (e.g., widths W1 and W2) along the heights of polysilicon structures 812B. In some embodiments, the plasma etch process can be performed at a temperature of about 25° C. to about 200° C. under a pressure from about 1 mTorr to about 800 mTorr. The flow rate of the etch gas, carrier gas, and passivation gas can be about 20 standard cubic centimeters per minute (sccm) to about 3000 sccm. A plasma power of about 10 W to about 4000 W and a bias power of about 300 W to about 600 W can be used in the plasma etch process.

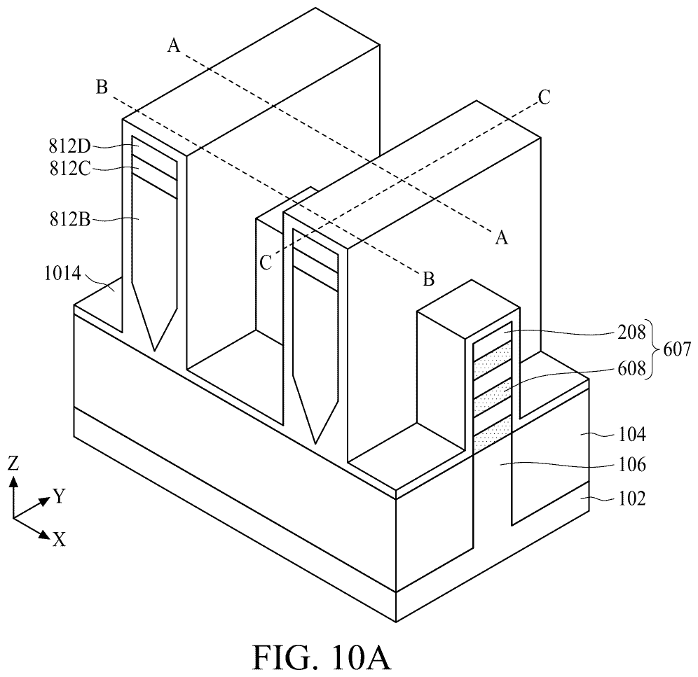

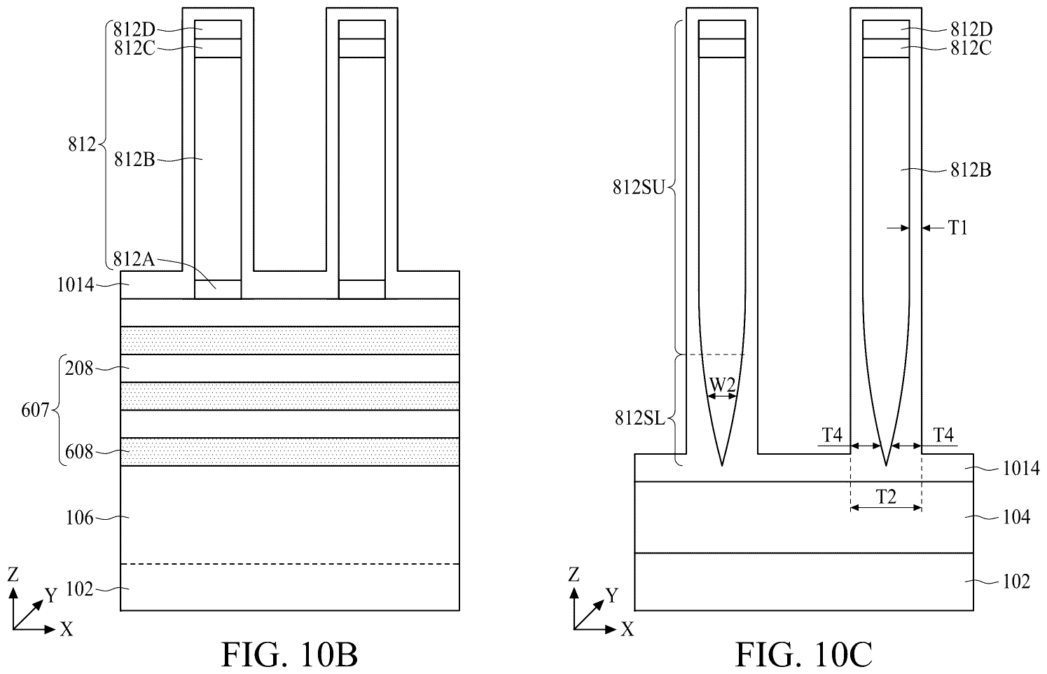

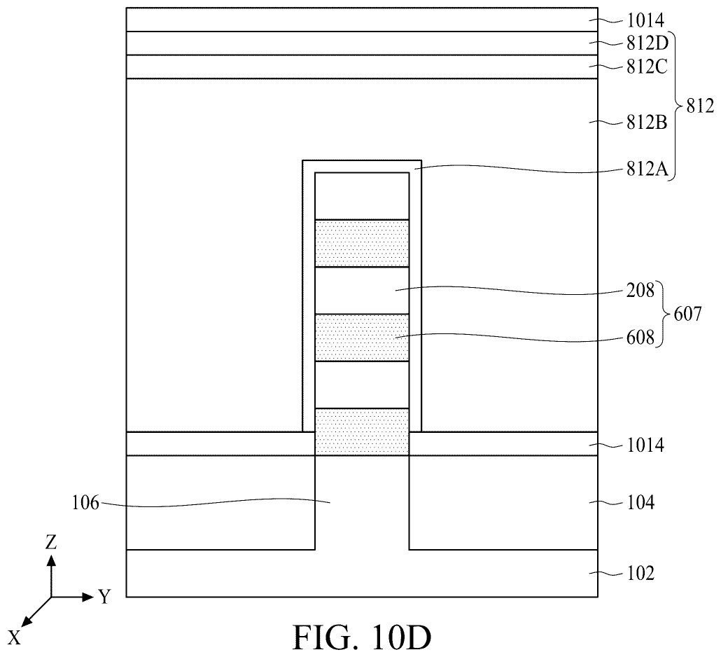

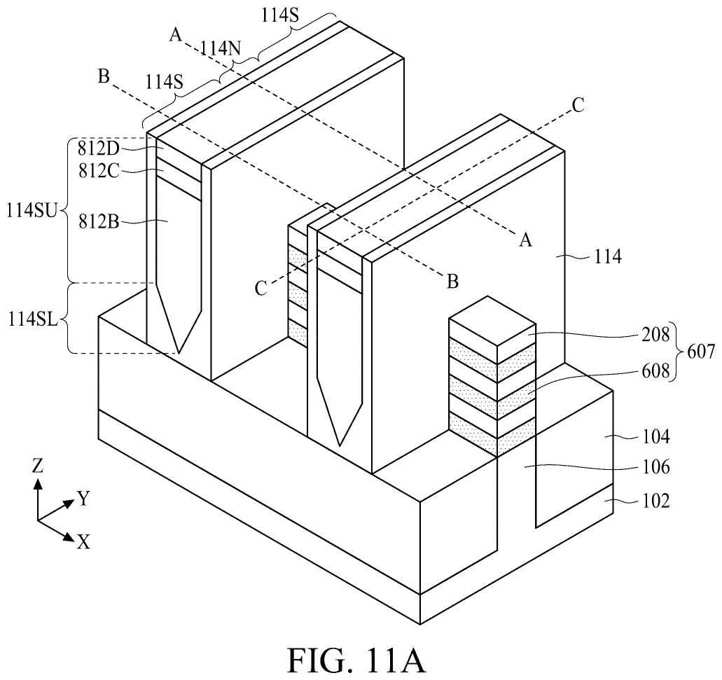

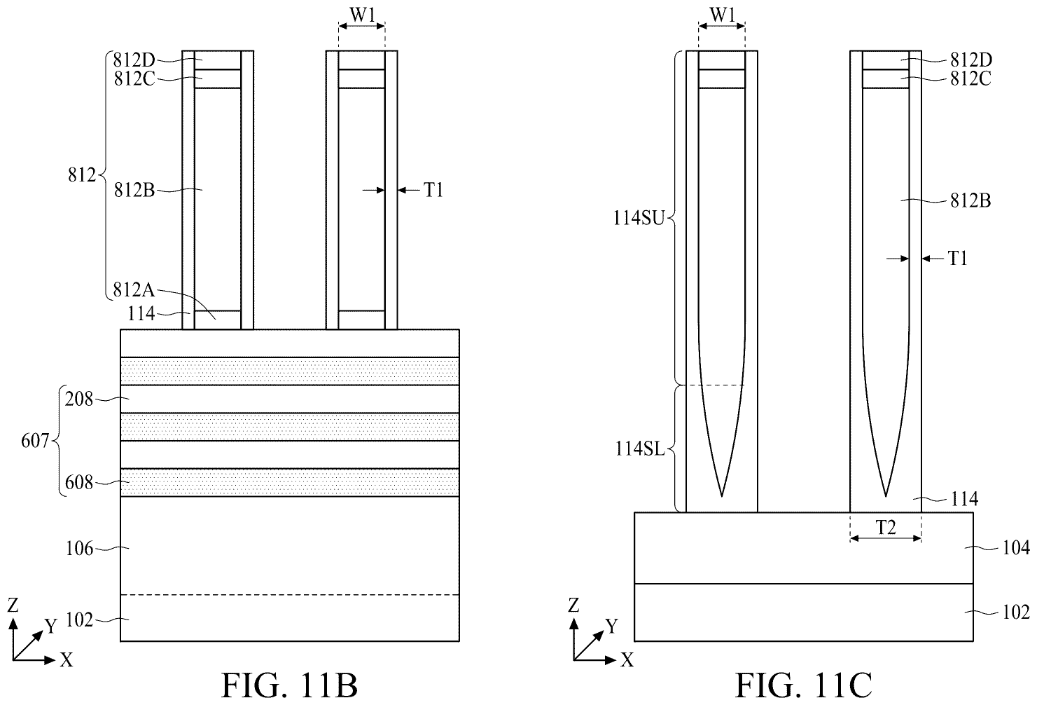

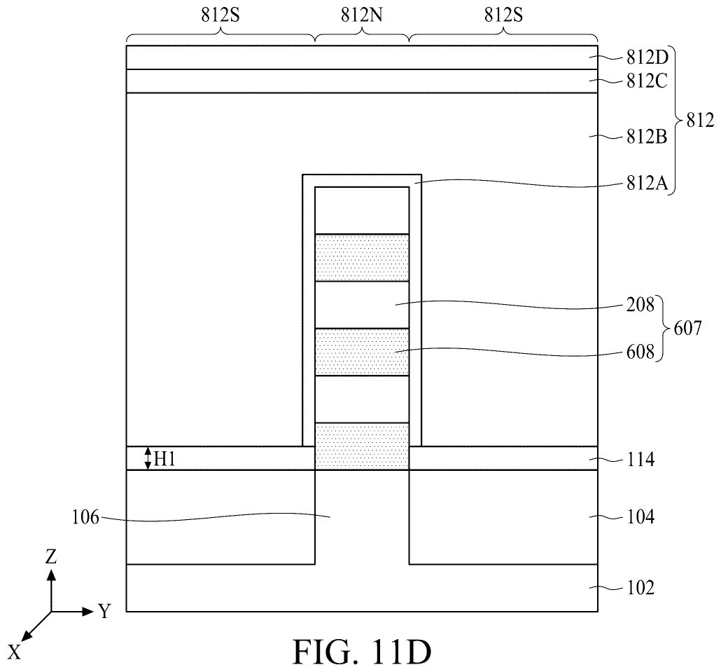

Referring to FIG. 5, in operation 520, an outer gate spacer is formed on the sacrificial gate structure. For example, as described with reference to FIGS. 10A-10D and 11A-11D, outer gate spacers 114 are formed on sacrificial gate structures 812. In some embodiments, the formation of outer gate spacers 114 can include sequential operations of (i) depositing a dielectric layer 1014 having the material of outer gate spacers 114 on the structures of FIGS. 9A-9D, as shown in FIGS. 10A-10D, (ii) performing an anneal process to densify the dielectric layer 1014, and (iii) performing an etch process on the densified dielectric layer 1014 to form outer gate spacers 114 with structural profiles as shown in FIGS. 11A-11D.

In some embodiments, dielectric layer 1014 can be deposited in a plasma enhanced CVD (PECVD) process using a gas mixture of TEOS, H₂, ammonia (NH₃), N₂, and/or O₂ at a temperature of about 500° C. to about 600° C. A plasma power of about 100 W to about 300 W and a bias power of about 200 W to about 500 W can be used in the PECVD process. In some embodiments, the bias applied to substrate 102 during the PECVD process can be controlled to vary the deposition selectivity of dielectric layer 1014 along the heights of sacrificial gate structures 812 to achieve the cross-sectional profile of dielectric layer 1014 of FIG. 10C having different thicknesses (e.g., thicknesses T1, T2, and T4) along the heights of polysilicon structures 812B. In some embodiments, dielectric layer 1014 can have thickness T1 surrounding the upper portions of polysilicon structures 812B in each of upper gate portions 812SU. In some embodiments, dielectric layer 1014 can have a thickness T4, greater than thickness T1, surrounding the lower portions of polysilicon structures 812B in lower gate portions 812SL, as shown in FIGS. 10A and 10C. In some embodiments, dielectric layer 1014 can have thickness T2, greater than thicknesses T1 and T4, surrounding the tips of polysilicon structures 812B in lower gate portions 812SL, as shown in FIGS. 10A and 10C. In some embodiments, the bias applied to substrate 102 during the PECVD process can be controlled to fill gap 926 (shown in FIGS. 9C and 9D) between polysilicon structure 812B and STI region 104, as shown in FIGS. 10C and 10D.

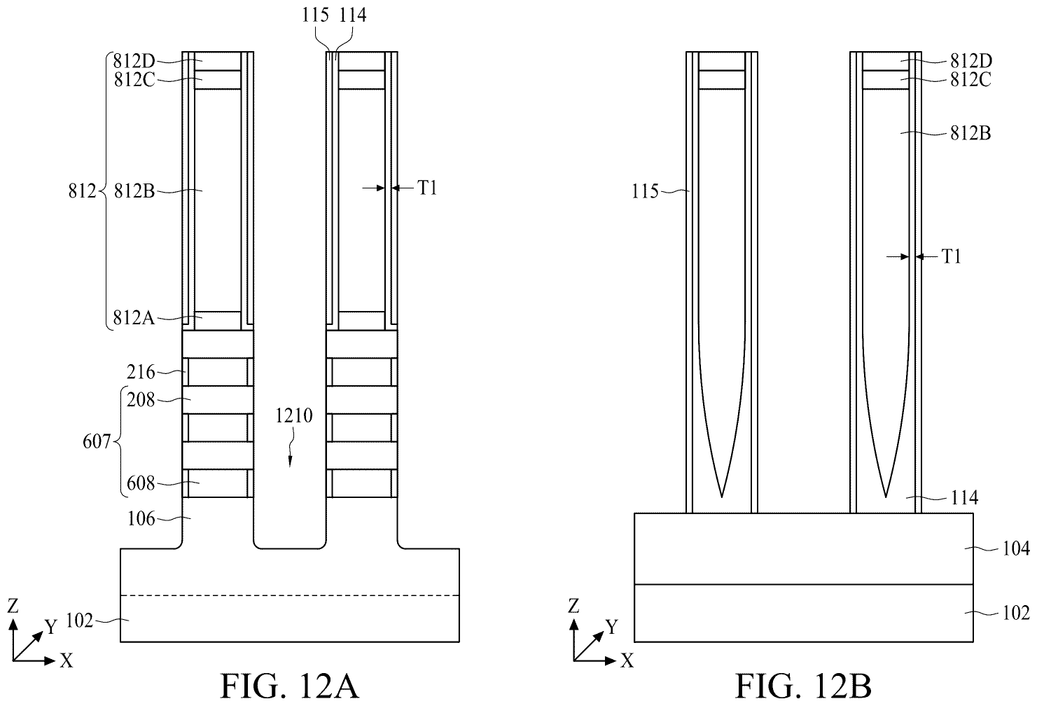

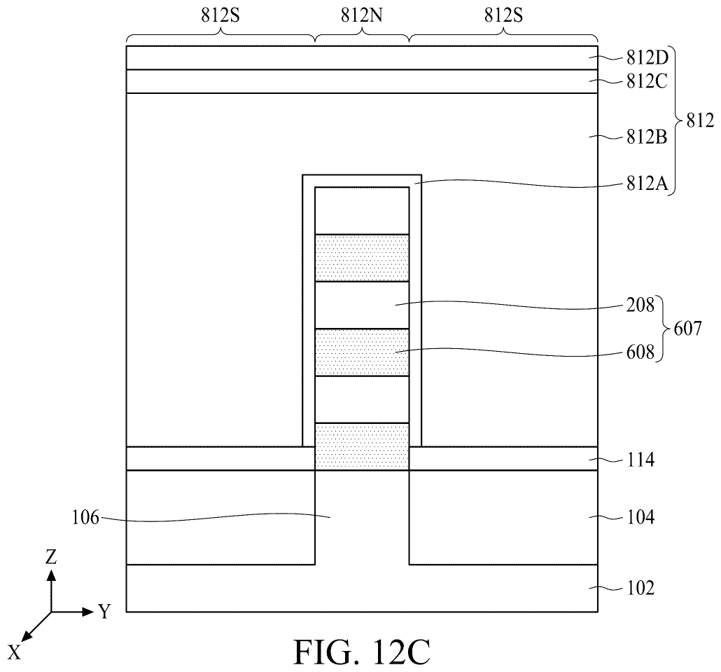

Referring to FIG. 5, in operation 525, S/D openings and inner gate spacers are formed in the superlattice structure. For example, as described with reference to FIGS. 12A-12C, S/D openings 1210 and inner gate spacers 216 are formed in superlattice structure 607. The formation of inner gate spacers 216 can include sequential operations of (i) performing an etch process on the structures of FIGS. 11A-11D to etch the portions of superlattice structure 607 not covered by sacrificial gate structures 812 and outer gate spacers 114 and form openings 1210, as shown in FIG. 12A (not visible in cross-sectional views of FIGS. 12B and 12C), (ii) performing an etch process on sidewalls of nanostructured sacrificial layers 608 facing openings 1210 to form inner gate spacer openings (not shown), (iii) depositing a dielectric layer (not shown) to fill the inner gate spacer openings, on sidewalls of outer gate spacers 114 and nanostructured layers 208, and on top surfaces of sacrificial gate structures 812, outer gate spacers 114, and base structure 106, and (iv) performing an etch process on the dielectric layer to form inner gate spacers 216 and barrier layers 115, as shown in FIGS. 12A and 12B (not visible in cross-sectional view of FIG. 12C).

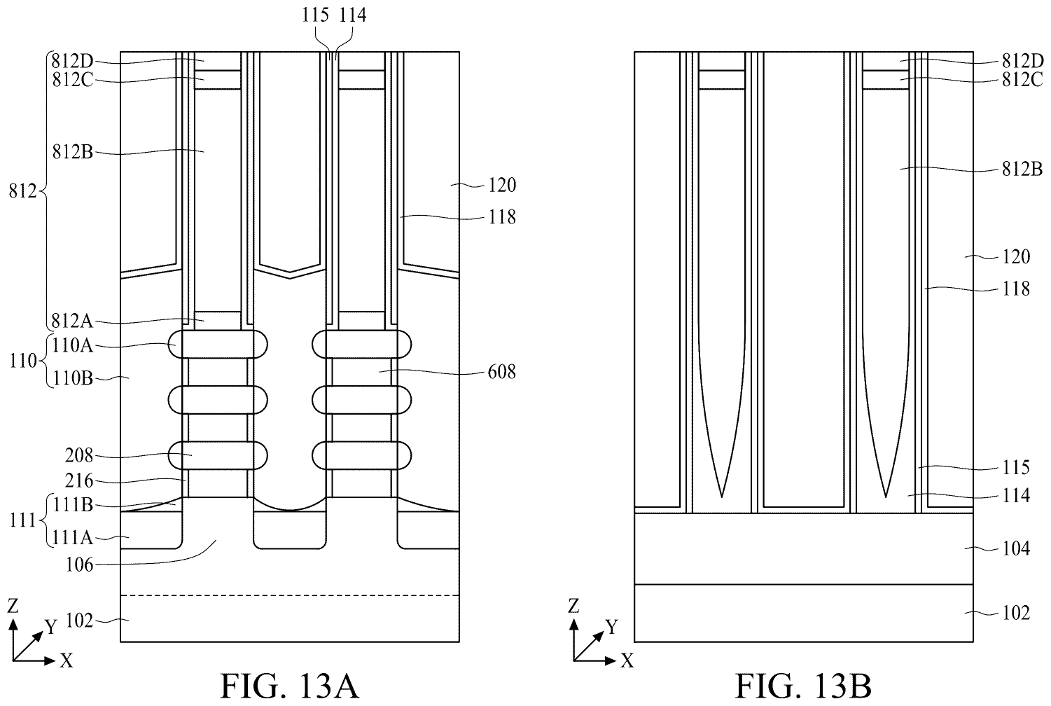

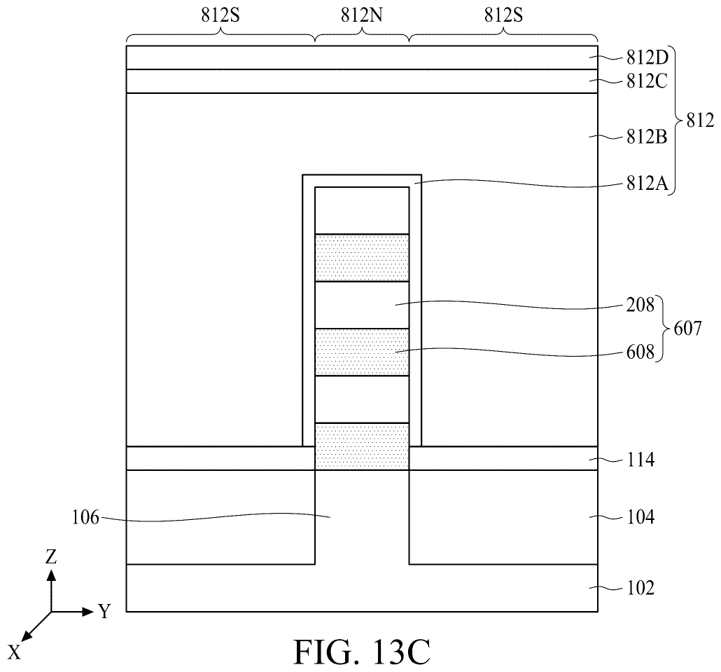

Referring to FIG. 5, in operation 530, isolation structures and S/D regions are formed in the S/D openings. For example, as described with reference to FIGS. 13A-13C, isolation structures 111 and S/D regions 110 are formed in S/D openings 1210. In some embodiments, the formation of isolation structures 111 can include sequential operations of (i) epitaxially growing an undoped silicon layer on the exposed surfaces of base structure 106 in S/D openings 1210 to form undoped semiconductor layer 111A, as shown in FIG. 13A (not visible in cross-sectional views of FIGS. 13B and 13C), and (ii) forming dielectric layer 111A on undoped semiconductor layer 111A, as shown in FIG. 13A (not visible in cross-sectional views of FIGS. 13B and 13C). In some embodiments, the formation of S/D regions 110 can include (i) epitaxially growing S/D sub-regions 110A on sidewalls of nanostructured layers 208, as shown in FIG. 13A (not visible in cross-sectional views of FIGS. 13B and 13C), and (ii) epitaxially growing S/D sub-regions 110B on S/D sub-regions 110A, as shown in FIG. 13A. The formation of S/D regions 110 can be followed by the formation of ESLs 118 and ILD layers 120, as shown in FIGS. 13A and 13B (not visible in cross-sectional view of FIG. 13C).

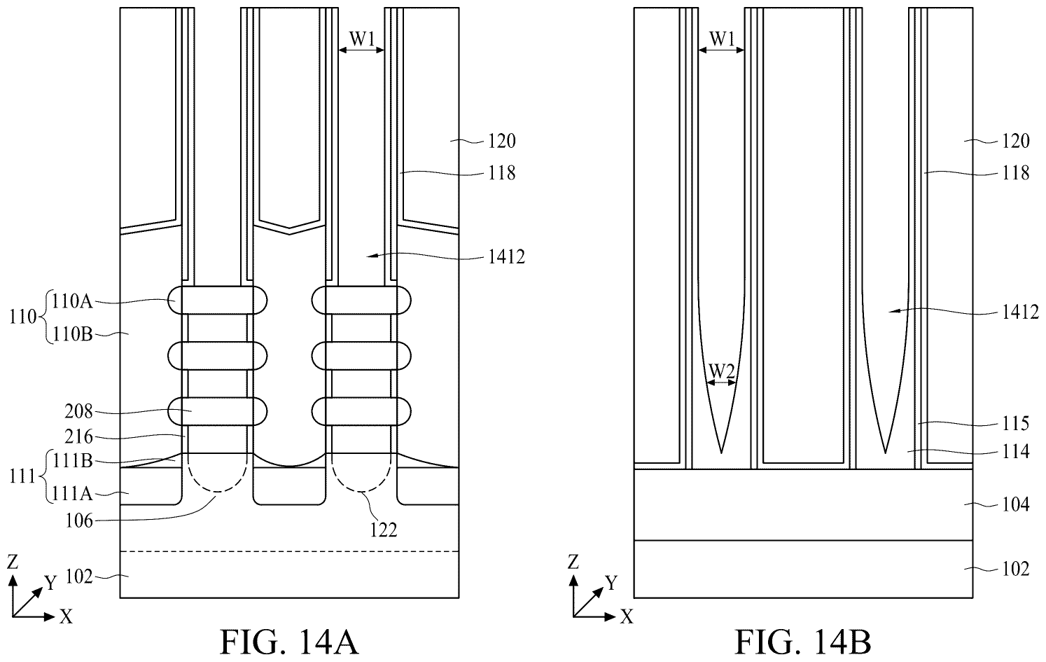

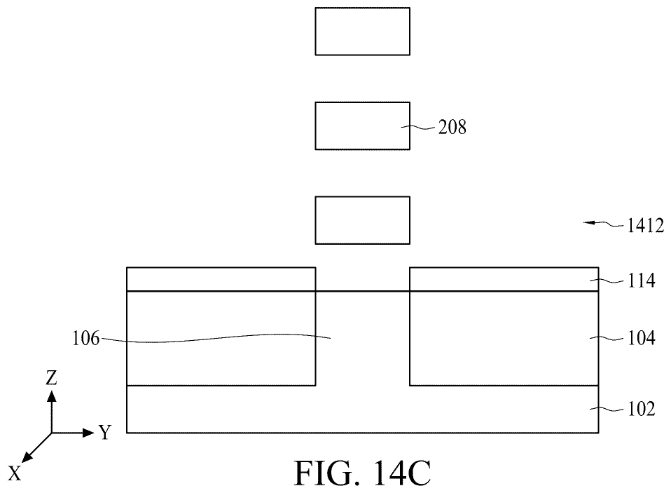

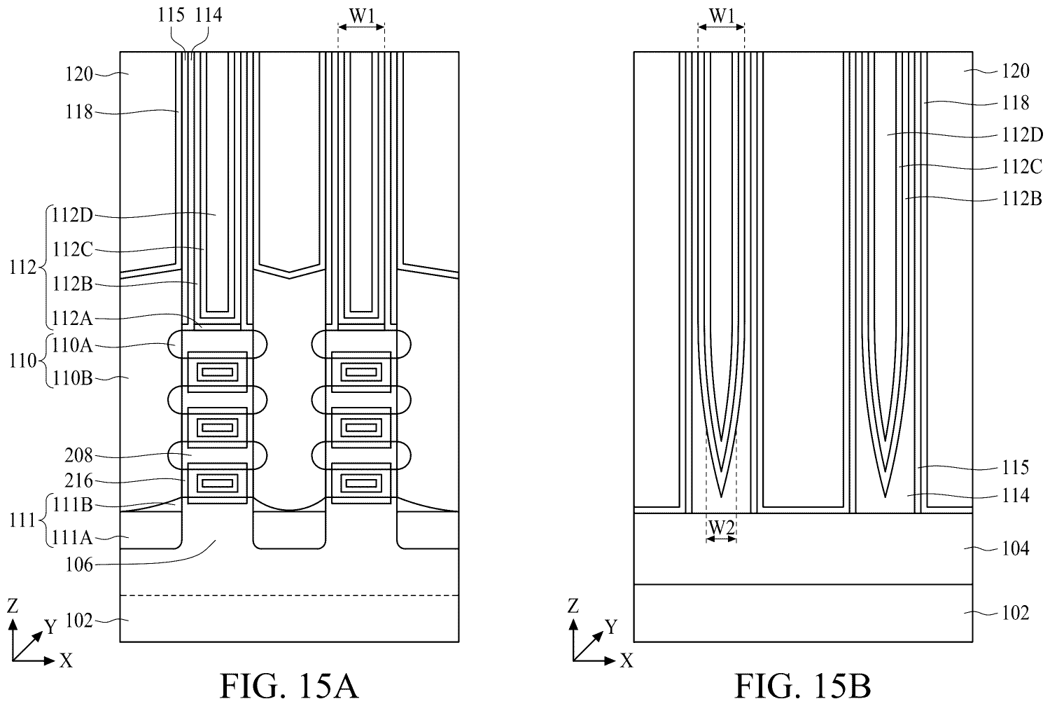

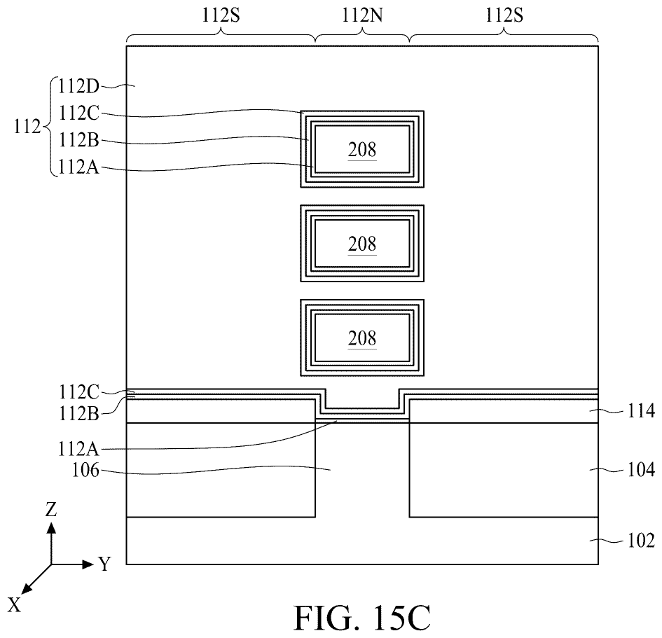

Referring to FIG. 5, in operation 535, the sacrificial gate structure and the nanostructured sacrificial layer are replaced with a GAA structure. For example, as described with reference to FIGS. 14A-14C and 15A-15C, sacrificial gate structures 812 and nanostructured sacrificial layers 608 are replaced with GAA structures 112. The formation of GAA structures 112 can include sequential operations of (i) etching sacrificial gate structures 812 and nanostructured sacrificial layers 608 to form gate openings 1412, as shown in FIGS. 14A-14C, (ii) performing an oxidation process on the exposed regions of nanostructured layers 208 in gate openings 1412 to form IL layers 112A, as shown in FIGS. 15A and 15C (not visible in cross-sectional view of FIG. 15B), (iii) forming HK gate dielectric layers 112B on IL layers 112A, as shown in FIGS. 15A-15C, (iv) forming WFM layers 112C on HK gate dielectric layers 112B, as shown in FIGS. 15A-15C, and (v) forming conductive layers 112D on WFM layers 112C, as shown in FIGS. 15A-15C.

In some embodiments, the cross-sectional profiles of gate openings 1412 on STI region 104, as shown in FIG. 14B, can be similar to the cross-sectional profiles of polysilicon structures 812B. Due to the tapered cross-sectional profiles of polysilicon structures 812B, less volume of polysilicon structures 812B are removed near STI regions 104 compared to the volume removed for polysilicon structures with non-tapered cross-sectional profiles in other GAA FETS. As a result, unlike the etch process for non-tapered polysilicon structures, polysilicon structures 812B are not over-etched to ensure complete removal of polysilicon structures 812B. Over-etching of non-tapered polysilicon structures leads to the formation of trenches (e.g., trenches 122 shown in dotted lines in FIG. 14A) in base structure 106, which increases parasitic capacitance in GAA FETs, as discussed above. Thus, due to the tapered cross-sectional profiles of polysilicon structures 812B and also due to the lower portions of polysilicon structures 812B being separated from STI regions 104 by outer gate spacers 114, gate openings 1412 can be prevented from extending into STI regions 104 and base structure 106 during the etching of sacrificial gate structures 812.

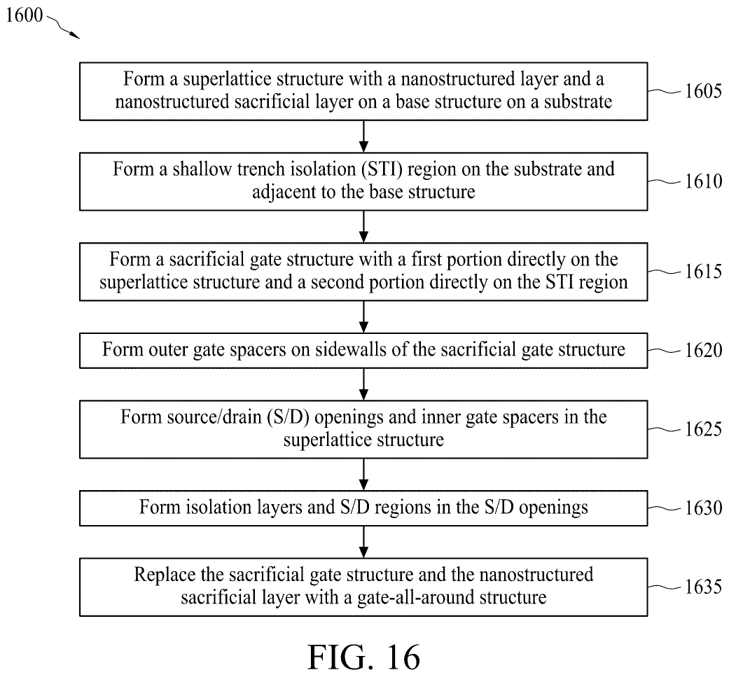

FIG. 16 is a flow diagram of an example method 1600 for fabricating GAA FET 100 with the top-down and cross-sectional views of FIGS. 1A, 1B, 3A-3C, and 4A-4C, according to some embodiments. For illustrative purposes, the operations illustrated in FIG. 16 will be described with reference to the example fabrication process for fabricating vas illustrated in FIGS. 6, 7A-7D, 17A-17D, 18A-18D, 19A-19D, 20A-20D, 21A-21C, 22A-22C, 23A-23C, 24A-24C, and 25A-25C. FIGS. 6, 7A, 17A, 18A, 19A, and 20A are isometric views of GAA FET 100 at various stages of its fabrication, according to some embodiments. FIGS. 7B, 17B, 18B, 19B, 20B, 21A, 22A, 23A, 24A, and 25A are cross-sectional views of GAA FET 100, along lines A-A of FIGS. 1A, 1B, 7A, 17A, 18A, 19A, and 20A, at various stages of its fabrication, according to some embodiments. FIGS. 7C, 17C, 18C, 19C, 20C, 21B, 22B, 23B, 24B, and 25B are cross-sectional views of GAA FET 100, along lines B-B of FIGS. 7A, 17A, 18A, 19A, and 20A, at various stages of its fabrication, according to some embodiments. FIGS. 7D, 17D, 18D, 19D, 20D, 21C, 22C, 23C, 24C, and 25C are cross-sectional views of GAA FET 100, along lines C-C of FIGS. 7A, 17A, 18A, 19A, and 20A, at various stages of its fabrication, according to some embodiments. Operations can be performed in a different order or not performed depending on specific applications. It should be noted that method 1600 may not produce a complete GAA FET 100. Accordingly, it is understood that additional processes can be provided before, during, and after method 1600, and that some other processes may only be briefly described herein. The discussion of elements in FIGS. 1A, 1B, 2A-2C, 3A-3C, 4A-4C, 2A-2C, 6, 7A-7D, 8A-8D, 9A-9D, 10A-10D, 11A-11D, 12A-12C, 13A-13C, 14A-14C, 15A-15C, 17A-17D, 18A-18D, 19A-19D, 20A-20D, 21A-21C, 22A-22C, 23A-23C, 24A-24C, and 25A-25C with the same annotations applies to each other, unless mentioned otherwise.

Referring to FIG. 16, operations 1605 and 1610 are similar to operations 505 and 510 of FIG. 5. After operation 1610, structure similar to the structure of FIG. 6 is formed. The subsequent operation 1615 of FIG. 16 is performed on the structures of FIG. 6, as described below with reference to FIGS. 7A-7D, 17A-17D, and 18A-18D.

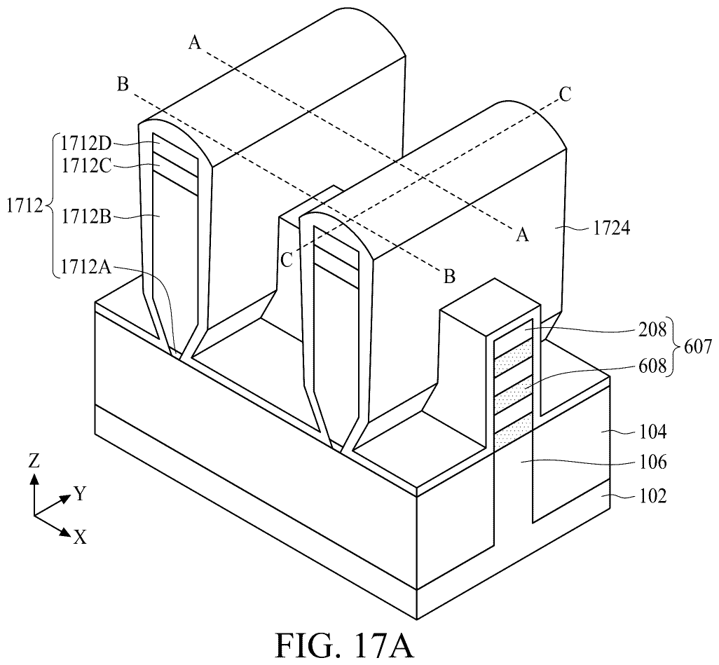

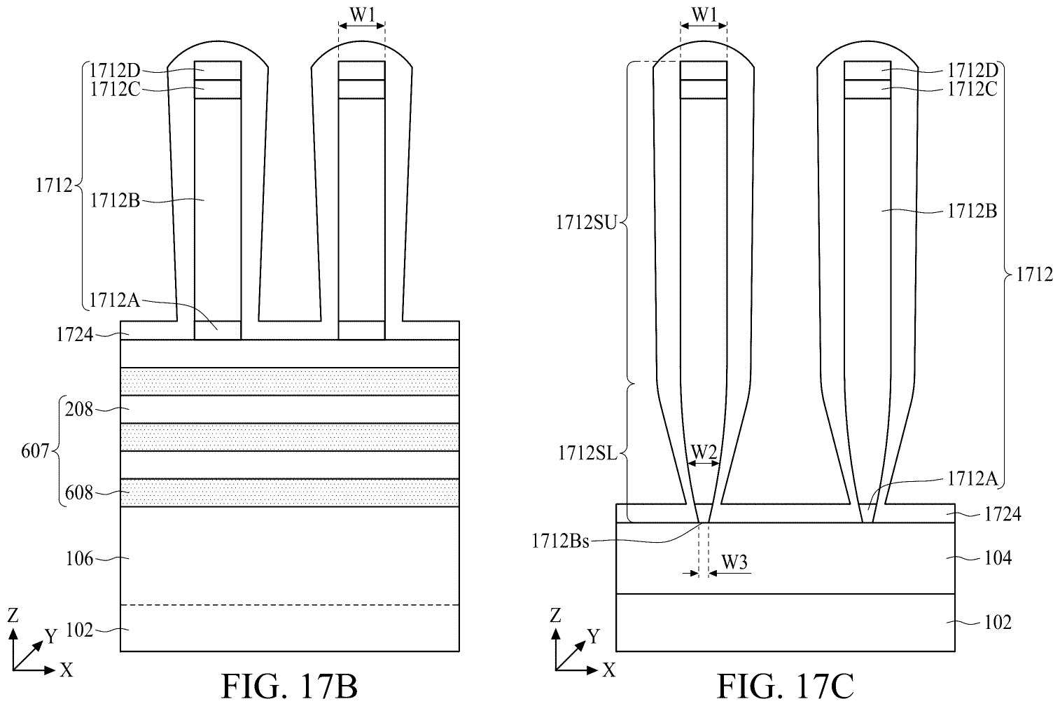

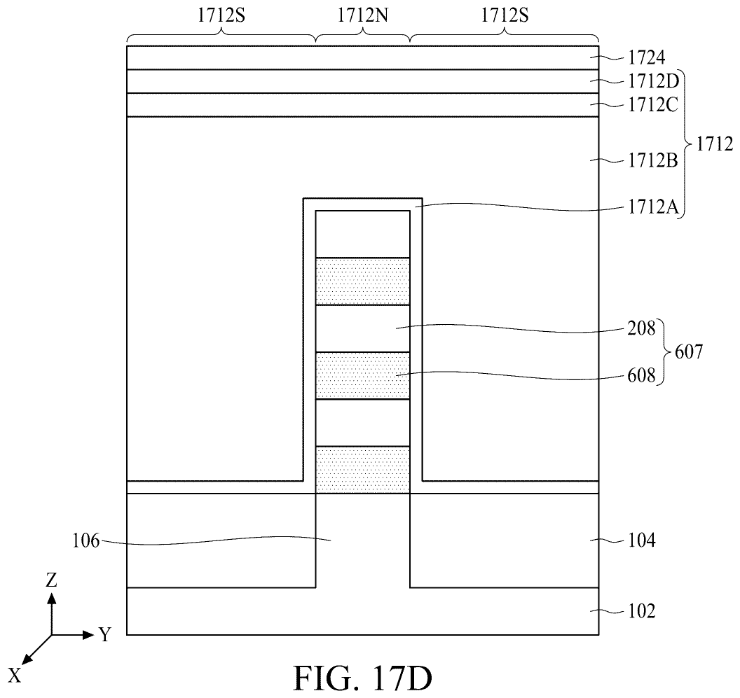

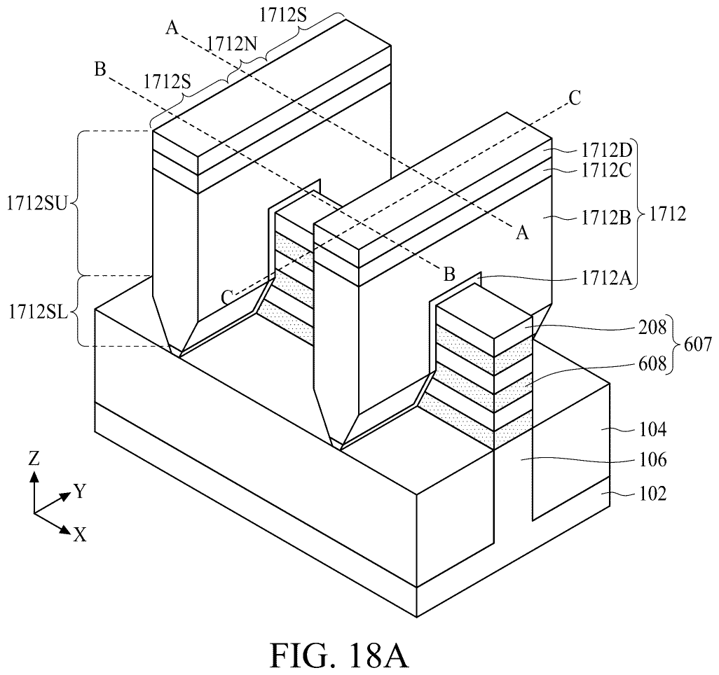

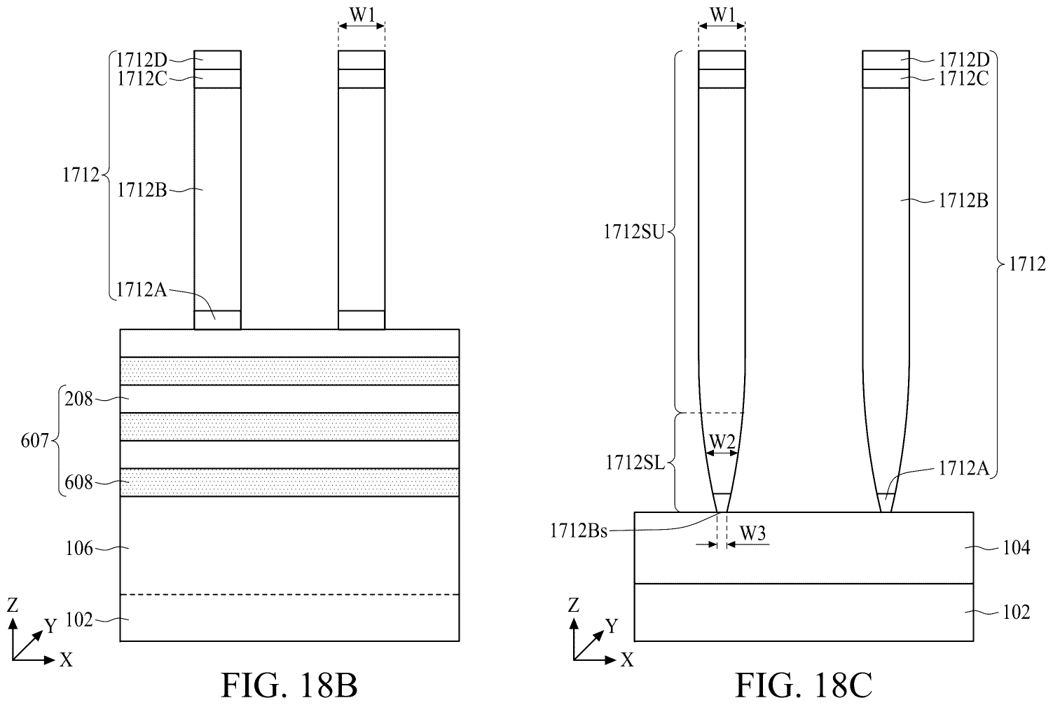

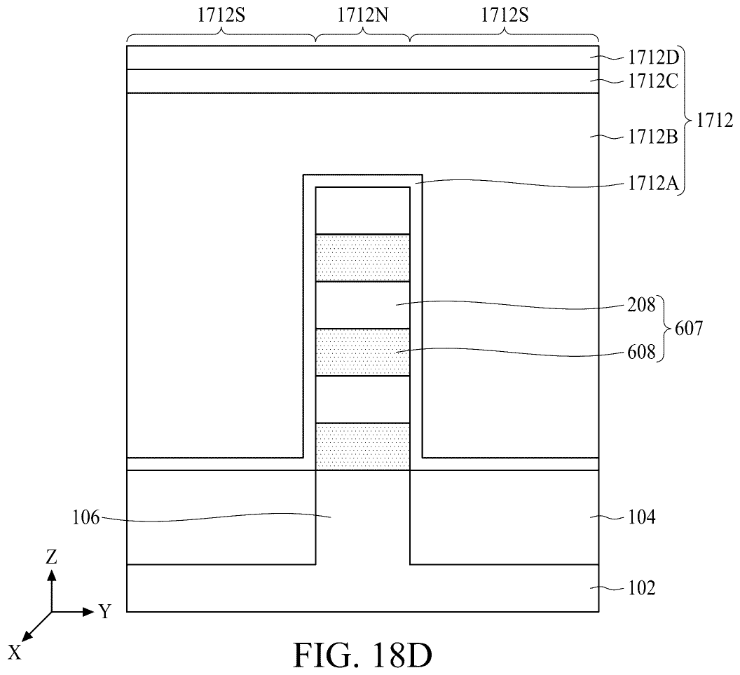

Referring to FIG. 16, in operation 1615, a sacrificial gate structure with a first portion directly on the superlattice structure and a second portion directly on the STI region is formed. For example, as described with reference to FIGS. 7A-7D, 17A-17D, and 18A-18D, sacrificial gate structure 1712 with outer gate portions 1712S directly on STI regions 104 and inner gate portion 1712N on superlattice structure 607 are formed. In some embodiments, the formation of sacrificial gate structure 1712 can include sequential operations of (i) depositing oxide layer 712A substantially conformally on STI regions 104 and superlattice structure 607 of FIG. 6, as shown in FIGS. 7A-7D, (ii) depositing amorphous, polycrystalline, or monocrystalline polysilicon layer 712B on oxide layer 712A, as shown in FIGS. 7A-7D, (iii) depositing nitride mask layer 712C (e.g., SiN layer) on polysilicon layer 712B, as shown in FIGS. 7A-7D, (iv) depositing oxide mask layer 712D (e.g., SiO₂ layer) on nitride mask layer 712C, as shown in FIGS. 7A-7D, (v) performing the lithographic patterning process (not shown) on the structures of FIGS. 7A-7D, (vi) performing the first etch process on the structures of FIGS. 7A-7D to form sacrificial gate structures 1712 having IL layers 1712A, polysilicon structures 1712B, nitride layers 1712C, and oxide layers 1712D, and a byproduct layer 1724, as shown in FIGS. 17A-17D, and (vii) performing the second etch process using HF acid gas or solution on the structures of FIGS. 17A-17D to remove byproduct layer 1724 and form sacrificial gate structures 1712 with outer gate portions 1712S directly on STI regions 104 and inner gate portion 1712N directly on superlattice structure 607, as shown in FIGS. 18A-18D.

Referring to FIGS. 17A-17D and 18A-18D, in some embodiments, each of outer gate portions 1712S can have (i) an upper gate portion 1712SU having a first portion of polysilicon structure 1712B, nitride layer 1712C, and oxide layer 1712D, and (ii) a lower gate portion 1712SL having a second portion of polysilicon structure 1712B. In some embodiments, the upper portion of polysilicon structure 1712B, nitride layer 1712C, and oxide layer 1712D in each of upper gate portions 812SU can have (i) rectangular cross-sectional profiles along an X-axis, (ii) substantially linear sidewalls, and (iii) widths W1 of about 9 nm to about 12 nm. In some embodiments, the lower portion of polysilicon structure 1712B in each of lower gate portions 1712SL can have (i) a tapered cross-sectional profile along an X-axis, (ii) sloped sidewalls, (iii) an angle of about 70 degrees to about 80 degrees between the sloped sidewall and top surface 104t of STI region 104, (iv) a substantially linear bottom surface 1712Bs in contact with top surface 104t of STI region 104, (v) width W2 of about 5 nm to about 8 nm in a middle region of lower gate portion 1712SL, and (vi) width W3 of about 0 nm to about 3 nm of bottom surface 1712Bs. In some embodiments, each of inner gate portions 1712N can be disposed on and in contact with topmost nanostructured layer 208 of superlattice structure 607. In some embodiments, each of inner gate portions 1712N can have (i) a rectangular cross-sectional profile along an X-axis, (ii) substantially linear sidewalls, and (iii) width W1 of about 9 nm to about 12 nm.

In some embodiments, unlike the first etch process in operation 515, portions of oxide layer 712A are retained at the interfaces between polysilicon structures 812B and STI regions 104 and between polysilicon structures 812B and superlattice structure 607 to form IL layers 1712A after the first etch process in operation 1615, as shown in FIGS. 17A-17D. In some embodiments, similar to byproduct layer 824, byproduct layer 1724 can be formed on sacrificial gate structures 1712 and exposed surfaces of superlattice structure 607 and STI regions 104 during the first etch process, as shown in FIGS. 17A-17D. The first etch process in operation 1615 can be similar to the first etch process in operation 515, except the etching duration can be shorter in the first etch process of operation 1615 compared to that of operation 515.

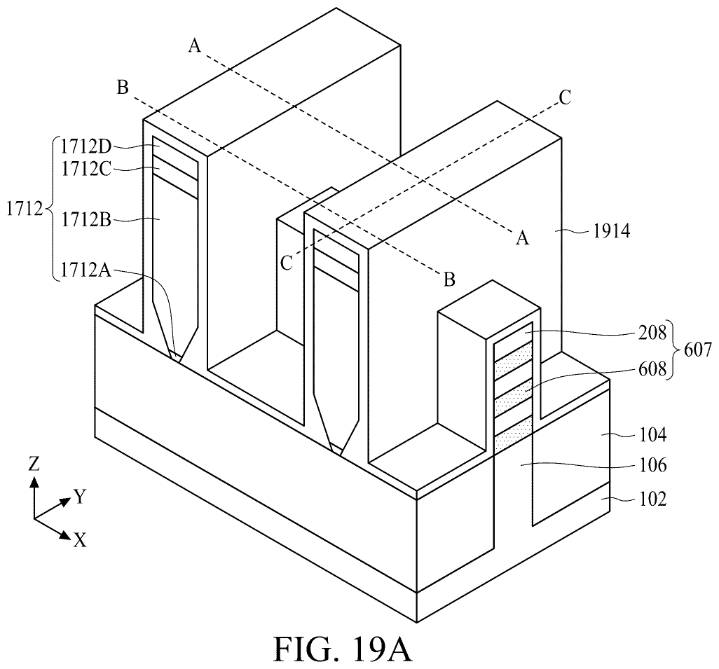

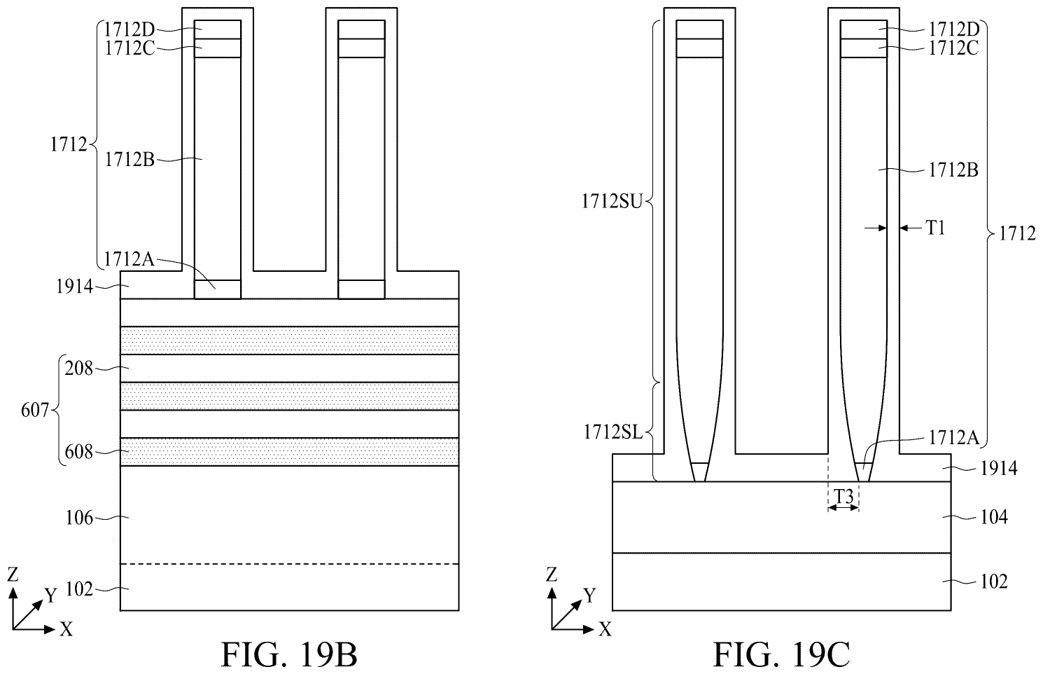

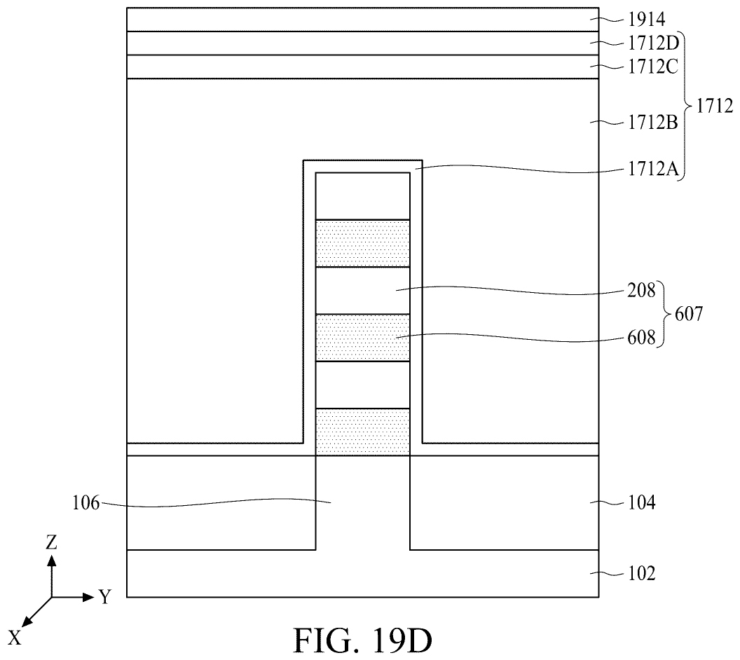

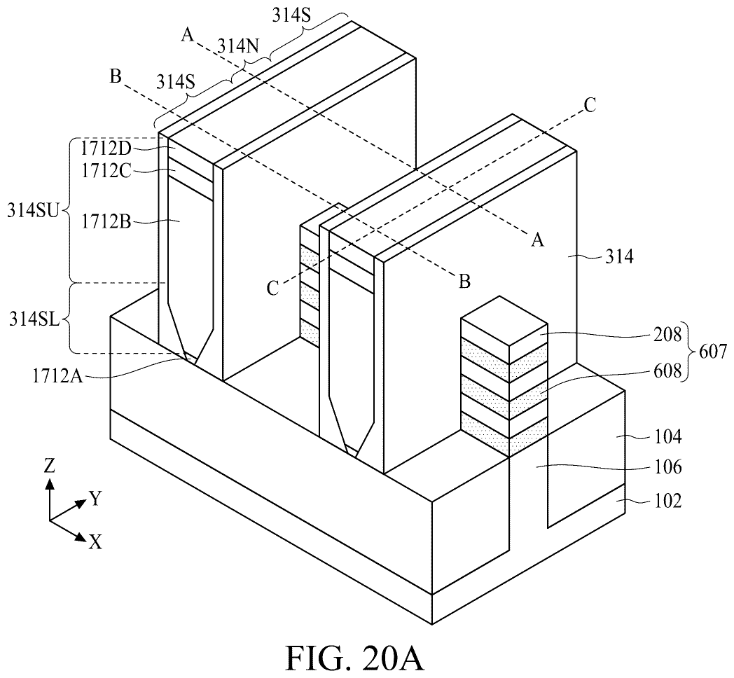

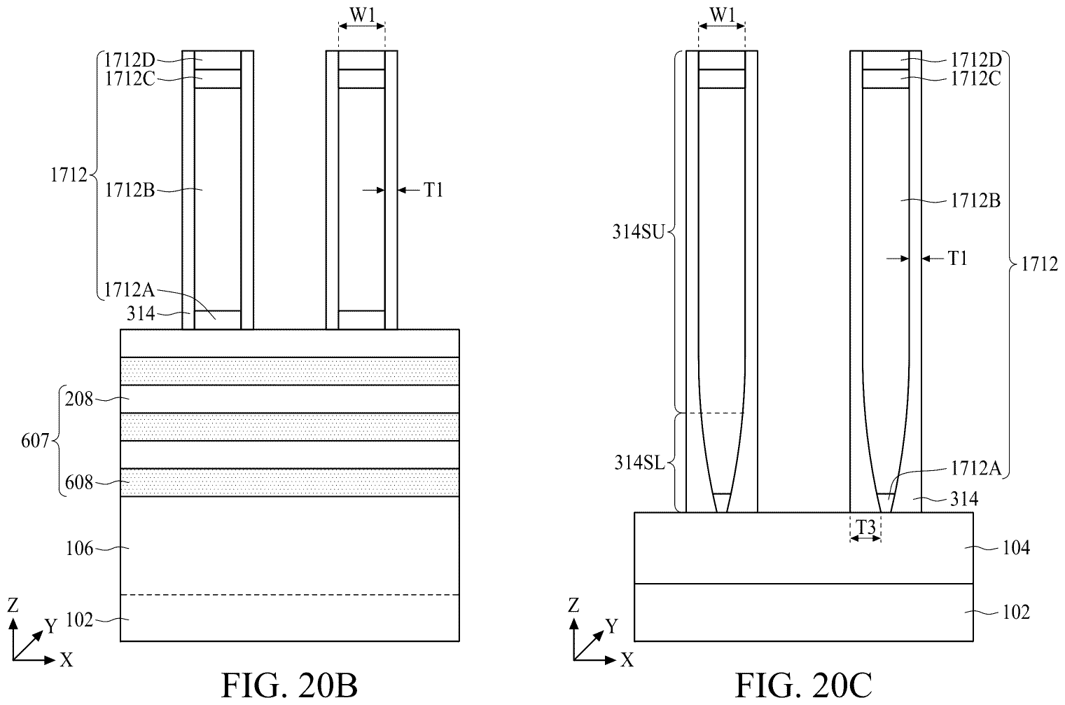

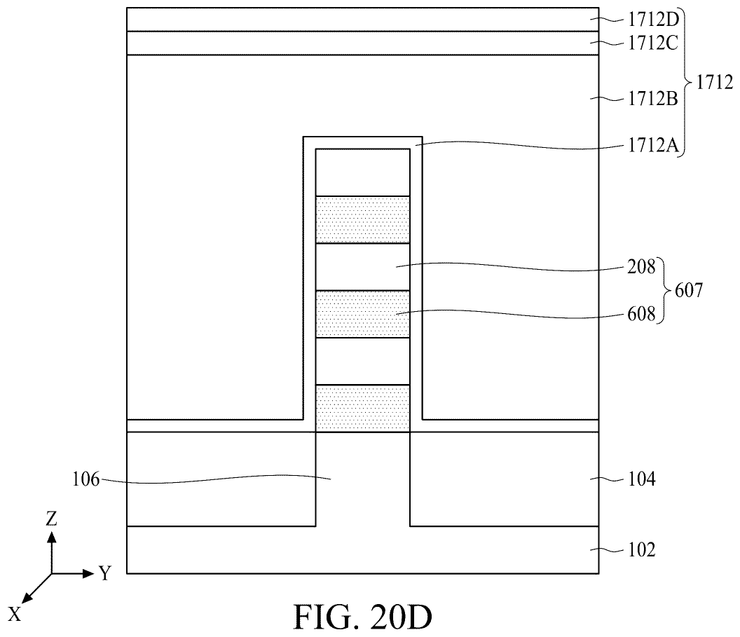

Referring to FIG. 16, in operation 1620, outer gate spacers are formed on sidewalls of the sacrificial gate structure. For example, as described with reference to FIGS. 19A-19D and 20A-20D, outer gate spacers 314 are formed on sidewalls of sacrificial gate structure 1712. In some embodiments, the formation of outer gate spacers 314 can include sequential operations of (i) depositing a dielectric layer 1914 having the material of outer gate spacers 314 on the structures of FIGS. 18A-18D, as shown in FIGS. 19A-19D, (ii) performing an anneal process to densify the dielectric layer 1914, and (iii) performing an etch process on the densified dielectric layer 1014 to form outer gate spacers 314 with structural profiles as shown in FIGS. 20A-20D.

In some embodiments, similar to dielectric layer 1014, dielectric layer 1914 can be deposited in the PECVD process. In some embodiments, the bias applied to substrate 102 during the PECVD process can be controlled to vary the deposition selectivity of dielectric layer 1914 along the heights of sacrificial gate structures 1712 to achieve the cross-sectional profile of dielectric layer 1914 of FIG. 19C having different thicknesses (e.g., thicknesses T1 and T3) along the heights of polysilicon structures 1712B. In some embodiments, dielectric layer 1914 can have thickness T1 surrounding the upper portions of polysilicon structures 1712B in upper gate portions 1712SU, as shown in FIG. 19C. In some embodiments, dielectric layer 1914 can have a thickness T3, greater than thickness T1, surrounding the lower portions of polysilicon structures 1712B in lower gate portions 1712SL, as shown in FIGS. 19A and 19C.

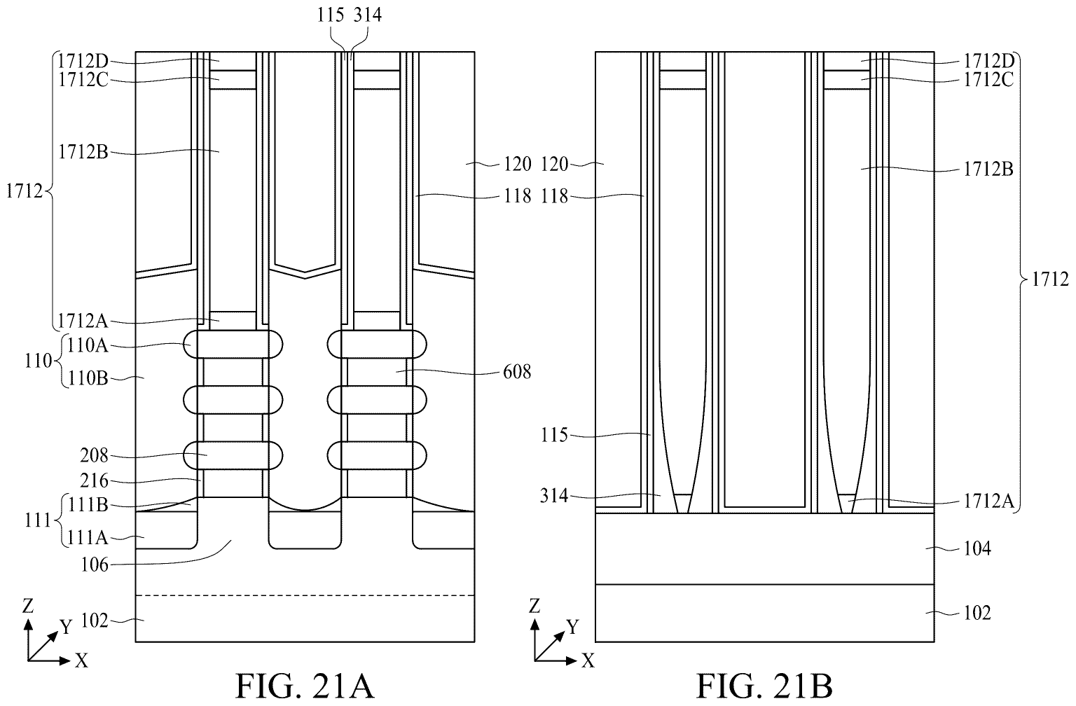

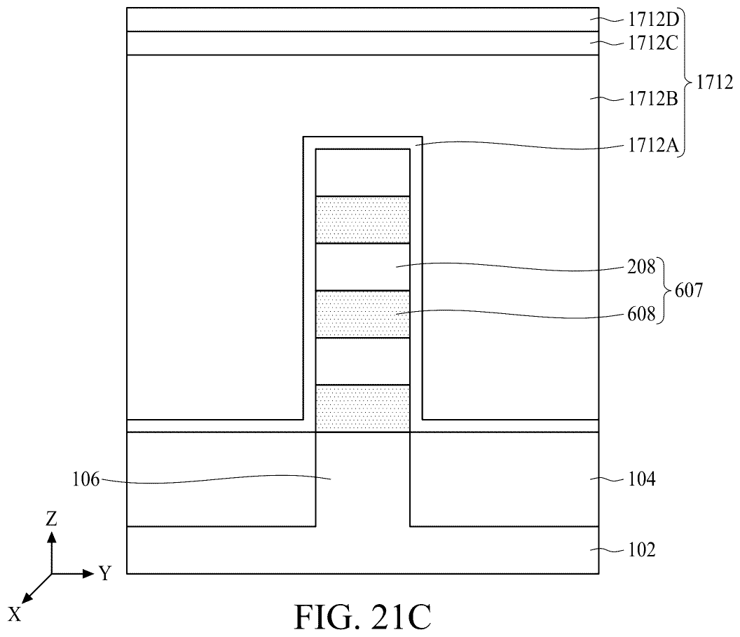

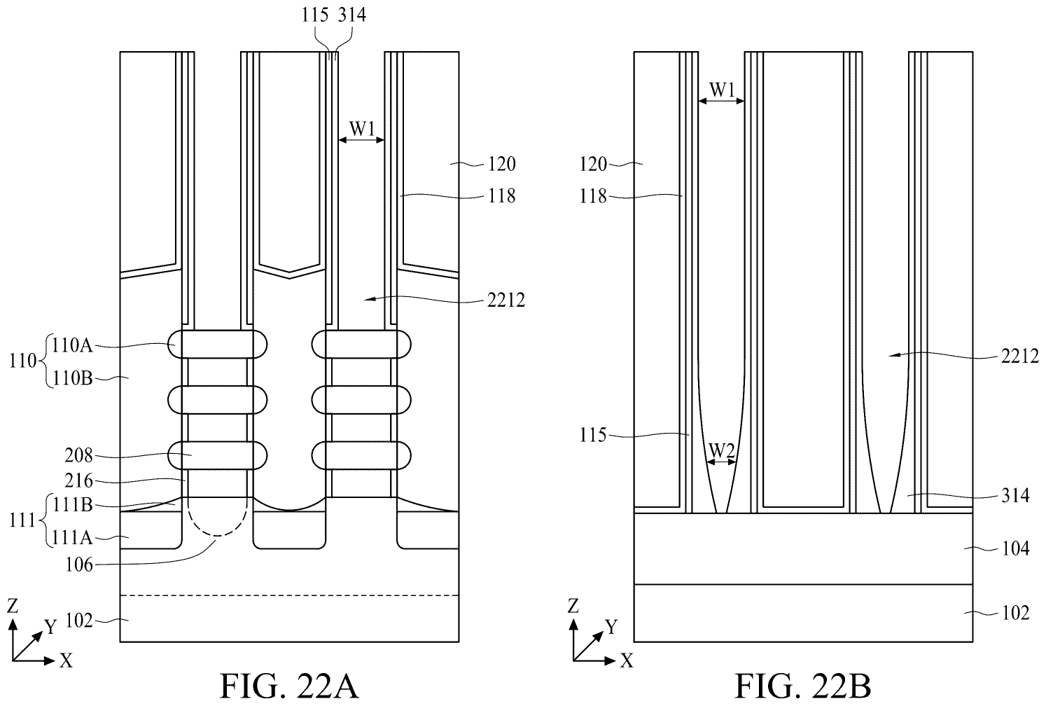

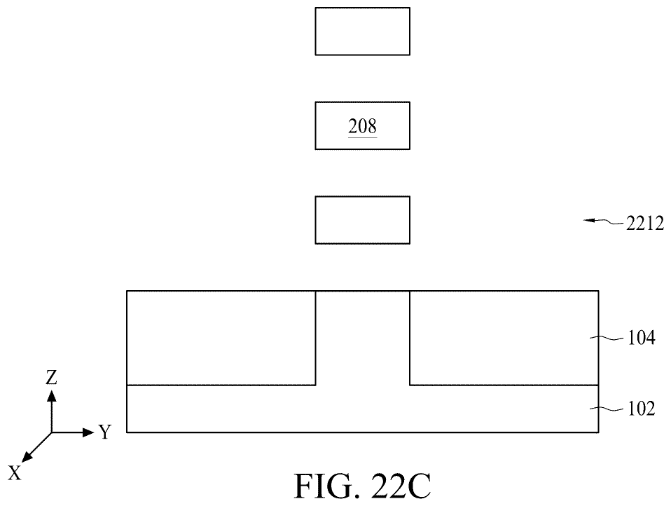

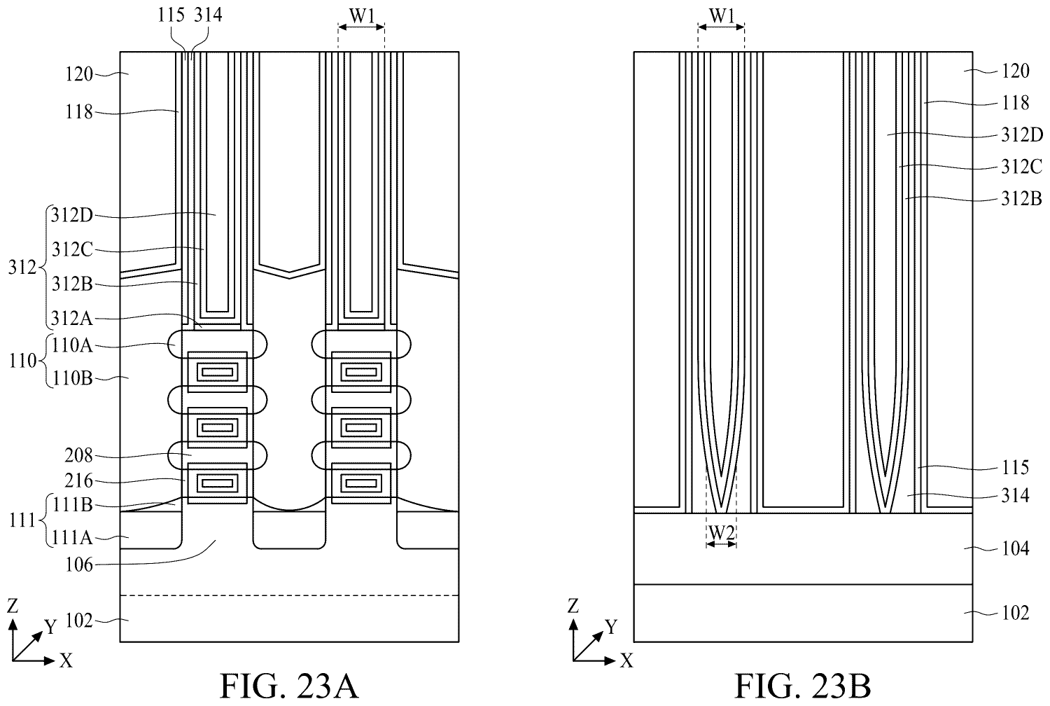

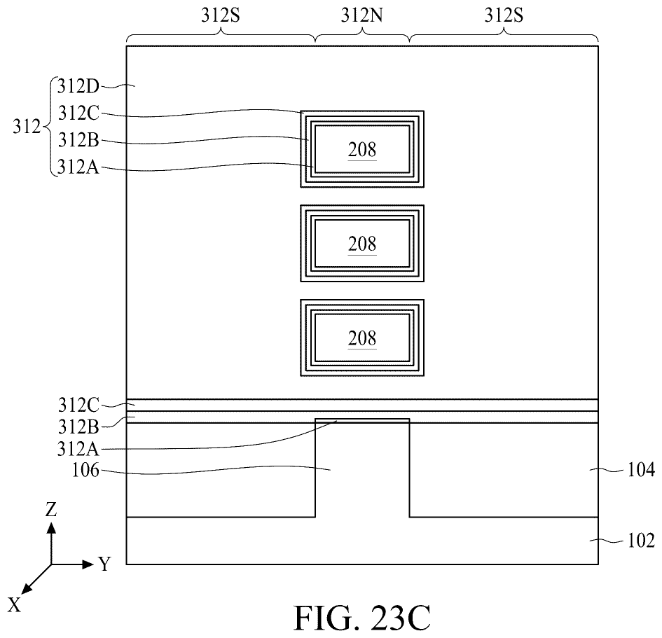

Referring to FIG. 16, operations 1625 and 1630 are similar to operations 525 and 530 of FIG. 5 and are performed on the structures of FIGS. 20A-20D. After operation 1630, structures of FIGS. 21A-21C are formed. The subsequent operation 1635 of FIG. 16 is performed on the structures of FIGS. 21A-21C, as described below with reference to FIGS. 22A-22C and 23A-23C.

Referring to FIG. 16, in operation 1635, the sacrificial gate structure and the nanostructured sacrificial layer are replaced with a GAA structure. For example, as described with reference to FIGS. 22A-22C and 23A-23C, sacrificial gate structures 1712 and nanostructured sacrificial layers 608 are replaced with GAA structures 312. The formation of GAA structures 312 can include sequential operations of (i) etching sacrificial gate structures 1712 and nanostructured sacrificial layers 608 to form gate openings 2212, as shown in FIGS. 22A-22C, (ii) performing an oxidation process on the exposed regions of nanostructured layers 208 in gate openings 2212 to form IL layers 312A, as shown in FIGS. 23A and 23C (not visible in cross-sectional view of FIG. 23B), (iii) forming HK gate dielectric layers 312B on IL layers 312A, as shown in FIGS. 23A-23C, (iv) forming WFM layers 312C on HK gate dielectric layers 312B, as shown in FIGS. 23A-23C, and (v) forming conductive layers 312D on WFM layers 312C, as shown in FIGS. 23A-23C.

In some embodiments, the cross-sectional profiles of gate openings 2212 on STI region 104, as shown in FIG. 14B, can be similar to the cross-sectional profiles of polysilicon structures 1712B. similar to polysilicon structures 812B, due to the tapered cross-sectional profiles of polysilicon structures 1712B, gate openings 2212 can be prevented from extending into STI regions 104 and base structure 106 during the etching of sacrificial gate structures 1712.

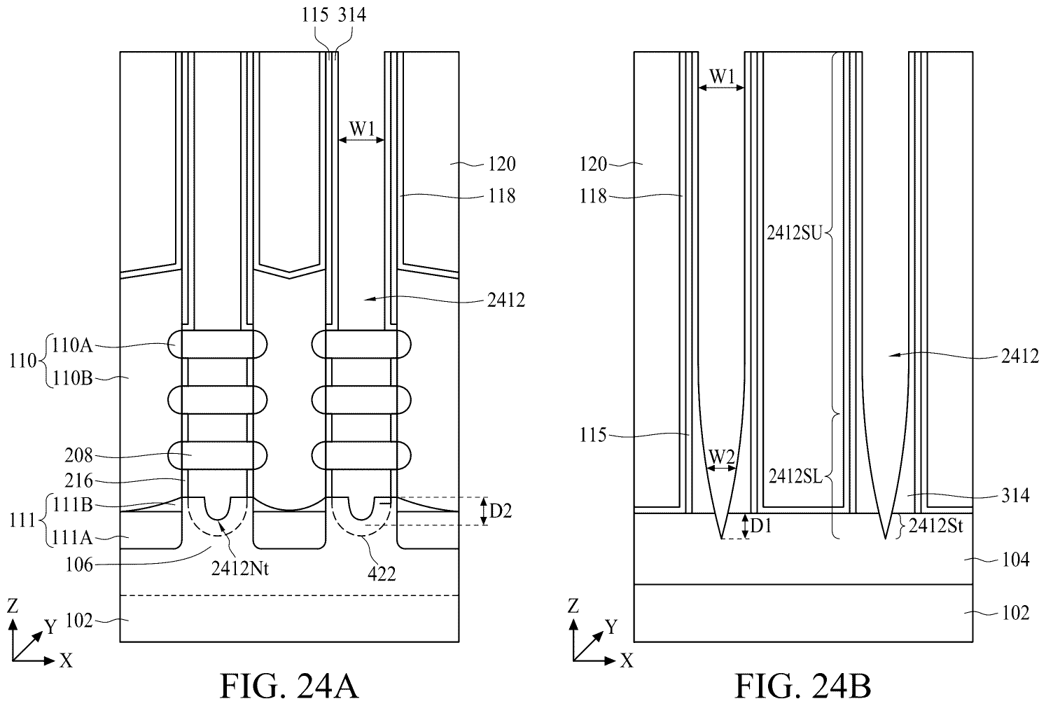

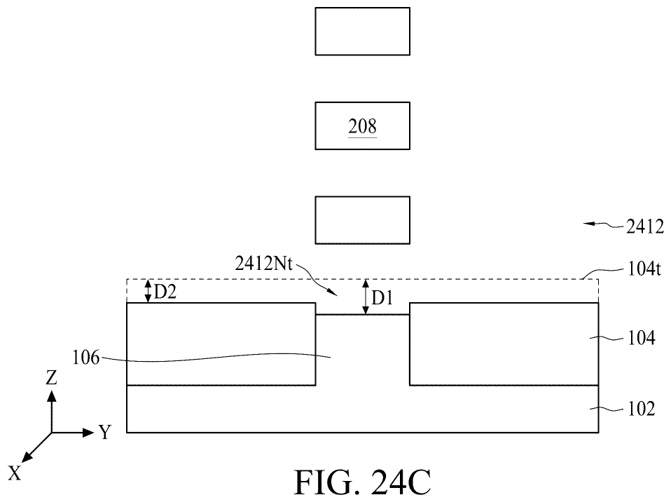

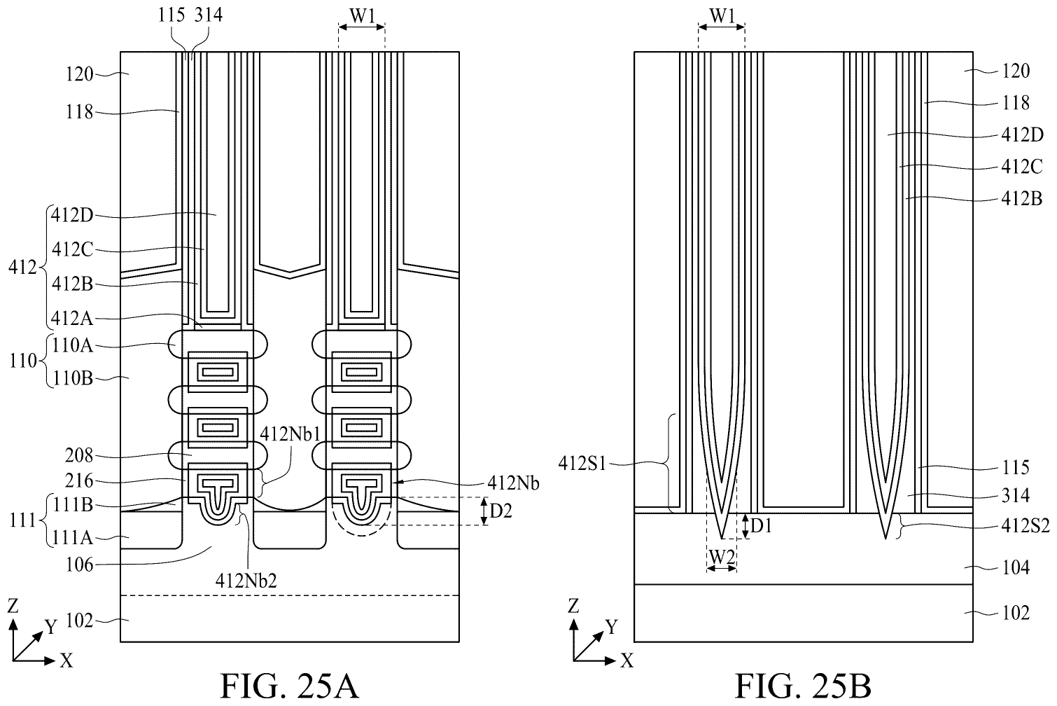

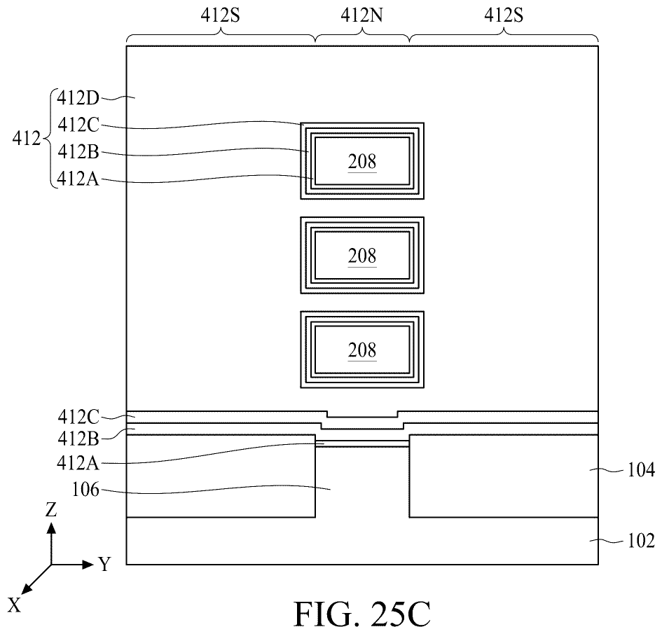

In some embodiments, in operation 1635, sacrificial gate structures 1712 and nanostructured sacrificial layers 608 can be replaced with GAA structures 412, as shown in FIGS. 25A-25C, instead of being replaced with GAA structures 312. The formation of GAA structures 412 can include sequential operations of (i) etching sacrificial gate structures 1712 and nanostructured sacrificial layers 608 to form gate openings 2412, as shown in FIGS. 24A-24C, (ii) performing an oxidation process on the exposed regions of nanostructured layers 208 in gate openings 2412 to form IL layers 412A, as shown in FIGS. 25A and 25C (not visible in cross-sectional view of FIG. 25B), (iii) forming HK gate dielectric layers 412B on IL layers 412A, as shown in FIGS. 25A-25C, (iv) forming WFM layers 412C on HK gate dielectric layers 412B, as shown in FIGS. 25A-25C, and (v) forming conductive layers 412D on WFM layers 412C, as shown in FIGS. 25A-25C.

In some embodiments, due to sacrificial gate structures 1712 having high aspect ratios (e.g., aspect ratio of about 3 to 20), sacrificial gate structures 1712 can be over-etched to ensure removal of the narrower portions sacrificial gate structures 1712 near STI regions 104. As a result of the over-etching, gate openings 2412 into STI regions 104 by a distance and into base structure 106 by a distance D2 to form trenches 2412Nt in base structure 106, as shown in FIG. 24A. Due to the tapered cross-sectional profiles of polysilicon structures 1712B, narrower trenches 2412Nt are formed compared to trenches (e.g., trenches 422 shown in dotted lines in FIG. 24A) formed from over-etching of polysilicon structures with non-tapered cross-sectional profiles in other GAA FETS. Also due to the tapered cross-sectional profiles of polysilicon structures 1712B, trenches 2412Nt are formed with shallower depth profiles than trenches 422.

The present disclosure provides example structures and methods for improving bottom surface profiles of bottom gate portion (e.g., bottom gate portions 212Nb, 312Nb, and 412Nb) of a GAA structure (e.g., GAA structure 112, 312, and 412), which increases the spacing (e.g., spacing S1) between the bottom gate portion and the S/D regions (e.g., S/D region 110). Increasing the spacing between the bottom gate portion and the S/D regions can reduce or minimize the parasitic capacitance in a GAA FET (e.g., GAA FET 100), which can improve the reliability and performance of the GAA FET. In some embodiments, the portion of the sacrificial gate structure (e.g., outer gate portion 812S) on the STI region (e.g., STI region 104) can be separated by a spacer (e.g., outer gate spacer 114 and 314) to prevent the etching of the STI region during the removal of the sacrificial gate structure. Preventing the etching of the STI region can prevent the etching of the base structure (e.g., base structure 106) and the formation of the trench in the base structure. As a result, the bottom gate portion can be formed with a substantially planar bottom surface profile. In some embodiments, the portion of the sacrificial gate structure (e.g., outer gate portion 1712S) directly on the STI region can be formed with a tapered cross-sectional profile to prevent or minimize the etching of the STI region during the removal of the sacrificial gate structure. As a result, the formation of the trench in the base structure can be prevented or a narrow trench (e.g., trench 2412Nt) can be formed in the base structure. In some embodiments, the trench can be narrower than that formed with sacrificial gate structures having non-tapered (e.g., rectangular) cross-sectional profiles on the STI regions. Thus, by modifying the sacrificial gate structure profiles, the bottom surface profiles of the bottom gate portion can be improved to reduce or minimize the parasitic capacitance in the GAA FET.

In some embodiments, a semiconductor device includes a substrate, a base structure with first and second base portions disposed on the substrate, an isolation region disposed on the substrate and adjacent to the base structure, a nanostructured channel region disposed on the first base portion, a source/drain region disposed on the second base portion, a gate structure, and a gate spacer disposed along sidewalls of the gate structure and between the gate structure and the isolation region. The gate structure includes an outer gate portion with a tapered cross-sectional profile and disposed on the isolation region and an inner gate portion with a non-tapered cross-sectional profile and disposed on the nanostructured channel region.

In some embodiments, a semiconductor device includes a substrate, a base structure with first and second base portions disposed on the substrate, a STI region disposed on the substrate, a nanostructured channel region disposed on the first base portion, a source/drain region disposed on the second base portion, and a gate structure. The gate structure includes a top gate portion disposed on the nanostructured channel region and a bottom gate portion. The bottom gate portion includes a first gate portion with a rectangular cross-sectional profile disposed on the first base portion and a second gate portion with a tapered cross-sectional profile disposed in the first base portion.

In some embodiments, a method includes forming a superlattice structure with a nanostructured layer and a sacrificial nanostructured layer on a base structure on a substrate, forming a STI region on the substrate, forming a sacrificial gate structure with a first gate portion suspended over the STI region and a second gate portion on the superlattice structure, forming a gate spacer along sidewalls of the sacrificial gate structure and between the sacrificial gate structure and the STI region, and replacing the sacrificial gate structure and the sacrificial nanostructured layer with a gate structure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a base structure with first and second base portions disposed on the substrate;
an isolation region disposed on the substrate and adjacent to the base structure;
a nanostructured channel region disposed on the first base portion;
a source/drain region disposed on the second base portion;
a gate structure, comprising:
an outer gate portion comprising a tapered cross-sectional profile and disposed on the isolation region, and
an inner gate portion comprising a non-tapered cross-sectional profile and disposed on the nanostructured channel region; and
a gate spacer disposed along sidewalls of the gate structure and between the gate structure and the isolation region.

2. The semiconductor device of claim 1, wherein the outer gate portion comprises:
an upper gate portion with a rectangular cross-sectional profile; and
a lower gate portion with the tapered cross-sectional profile.

3. The semiconductor device of claim 1, wherein the outer gate portion comprises:
an upper gate portion with a first width; and
a lower gate portion with a second width smaller than the first width.

4. The semiconductor device of claim 1, wherein the gate structure comprises a gate dielectric layer with a V-shaped cross-sectional profile disposed on the isolation region.

5. The semiconductor device of claim 1, wherein the gate structure comprises a conductive layer, and
wherein a portion of the gate spacer is disposed between a bottom surface of the conductive layer and a top surface of the isolation region.

6. The semiconductor device of claim 1, wherein the gate spacer comprises:
an upper spacer portion with a first thickness; and
a lower spacer portion with a second thickness greater than the first thickness.

7. The semiconductor device of claim 1, wherein the gate spacer comprises:
an outer sidewall with a substantially linear profile facing away from the gate structure; and
an inner sidewall with a V-shaped cross-sectional profile facing toward the gate structure.

8. The semiconductor device of claim 1, wherein a first portion of the gate structure disposed on the gate spacer is at a higher surface plane than a second portion of the gate structure disposed on the first base portion of the base structure.

9. The semiconductor device of claim 1, wherein the gate spacer is disposed under a tapered portion of the outer gate portion.

10. The semiconductor device of claim 1, further comprising an isolation structure disposed between the source/drain region and the second base portion.

11. A semiconductor device, comprising:
a substrate;
a base structure with first and second base portions disposed on the substrate;
a shallow trench isolation (STI) region disposed on the substrate;
a nanostructured channel region disposed on the first base portion;
a source/drain region disposed on the second base portion; and
a gate structure, comprising:
a top gate portion disposed on the nanostructured channel region, and
a bottom gate portion, comprising:
a first gate portion with a rectangular cross-sectional profile disposed on the first base portion; and
a second gate portion with a tapered cross-sectional profile disposed in the first base portion.

12. The semiconductor device of claim 11, wherein the gate structure further comprises an outer gate portion, comprising:
an upper gate portion disposed on the STI region; and
a lower gate portion disposed in the STI region.

13. The semiconductor device of claim 11, wherein the gate structure further comprises an outer gate portion, comprising:
an upper gate portion with a rectangular cross-sectional profile; and
a lower gate portion with a V-shaped cross-sectional profile.

14. The semiconductor device of claim 11, wherein the gate structure further comprises an outer gate portion that extends into the STI region by a first distance; and
wherein the second gate portion extends into the first base portion by a second distance that is greater than the first distance.

15. The semiconductor device of claim 11, further comprising a gate spacer disposed on the STI region, comprising:
an outer sidewall with a substantially linear profile facing away from the gate structure; and
an inner sidewall with a sloped profile facing toward the gate structure.

16. The semiconductor device of claim 11, wherein the second gate portion extends a distance of about 2 nm to about 4 nm into the first base portion.

17. A method, comprising:
forming a superlattice structure with a nanostructured layer and a sacrificial nanostructured layer on a base structure on a substrate;
forming a shallow trench isolation (STI) region on the substrate;
forming a sacrificial gate structure with a first gate portion suspended over the STI region and a second gate portion on the superlattice structure;
forming a gate spacer along sidewalls of the sacrificial gate structure and between the sacrificial gate structure and the STI region; and
replacing the sacrificial gate structure and the sacrificial nanostructured layer with a gate structure.

18. The method of claim 17, wherein forming the sacrificial gate structure comprises:
forming the first gate portion with a tapered cross-sectional profile; and
forming the second gate portion with a rectangular cross-sectional profile.

19. The method of claim 17, wherein forming the sacrificial gate structure comprises:
forming the first gate portion with a first width; and
forming the second gate portion with a second width smaller than the first width.

20. The method of claim 17, wherein forming the gate spacer comprises depositing a dielectric layer to cover a top surface and sidewalls of the sacrificial gate structure and to fill a gap between the sacrificial gate structure and the STI region.
